(19) United States
(12) Patent Application Publication
(10) Pub. No.: US 2026/0181892 A1
(43) Pub. Date: Jun. 25, 2026

(54) SEMICONDUCTOR DEVICE AND ELECTRONIC SYSTEM INCLUDING SEMICONDUCTOR DEVICE

(71) Applicant: Samsung Electronics Co., Ltd., Suwon-si (KR)

(72) Inventors: HYOJOON RYU, Suwon-si (KR); Yunna Um, Suwon-si (KR); Eunjin Kim, Suwon-si (KR); Hanna Park, Suwon-si (KR); JAE-HWANG SIM, Suwon-si (KR); EUNTAEK JUNG, Suwon-si (KR)

(21) Appl. No.: 19/273,938

(22) Filed: Jul. 18, 2025

(30) Foreign Application Priority Data
Dec. 19, 2024 (KR) 10-2024-0191765

(51) Int. Cl. H10B 43/27; H10B 43/10; H10B 43/40

(52) U.S. Cl. CPC H10B 43/27; H10B 43/10; H10B 43/40

(57) ABSTRACT

A semiconductor device according to an embodiment includes a circuit region including a peripheral circuit structure positioned on a substrate and a cell region positioned adjacent to the circuit region and including a cell array region and a connection region, wherein the cell region includes a gate stacking structure including an interlayer insulating layer and a gate electrode alternately stacked on a substrate, a channel structure positioned in the cell array region and penetrating the gate stacking structure, a gate contact part that is electrically connected to the circuit region through the gate stacking structure in the connection region, and is electrically connected to a connection gate electrode among the plurality of gate electrodes and is insulated from the remaining gate electrodes by an insulating pattern, and a dummy structure penetrating the gate stacking structure and being insulated from the circuit region and the gate electrode, and positioned with the gate electrode via an insulating pattern interposed therebetween, the insulating pattern adjacent to the gate contact part includes a first insulating pattern positioned along the circumference of the space in which the insulating pattern is formed, a second insulating pattern positioned between the first insulating pattern, and a third insulating pattern capping the space in which the insulating pattern is formed, the insulating pattern positioned adjacent to the dummy structure includes a first insulating pattern positioned along the circumference of the space in which the insulating pattern is formed, a second insulating pattern positioned between the first insulating pattern, and a third insulating pattern capping the space in which the insulating pattern is formed, the third insulating pattern includes SiN, and the thickness of the third insulating pattern positioned adjacent to the gate contact part in a direction parallel to the substrate is thicker than the thickness of the third insulating pattern positioned adjacent to the dummy structure in a direction parallel to the substrate.

### CROSS-REFERENCE TO RELATED APPLICATION

This application claims priority to and the benefit of Korean Patent Application No. 10-2024-0191765 filed with the Korean Intellectual Property Office on Dec. 19, 2024, the entire contents of which are incorporated herein by reference.

### BACKGROUND OF THE DISCLOSURE

### Field of the Disclosure

The present disclosure relates to a semiconductor device and an electronic system including a semiconductor device.

### Description of the Related Art

In electronic systems that require a data storage, a semiconductor device capable of storing a high-capacity data is often required. Accordingly, methods to increase the data storage capacity of the semiconductor devices are being researched. For example, as one of the methods for increasing the data storage capacity of the semiconductor device, the semiconductor device including memory cells arranged three-dimensionally instead of two-dimensionally is being proposed.

### SUMMARY OF THE DISCLOSURE

The embodiments aim to provide a semiconductor device and an electronic system including a semiconductor device that may improve reliability.

A semiconductor device according to an embodiment includes a substrate including a peripheral circuit region; and a cell region positioned adjacent to the peripheral circuit region and including a cell array region and a connection region. The cell region includes: a gate stack including interlayer insulating layers and gate electrodes alternately stacked on the substrate, a channel pattern positioned in the cell array region and penetrating the gate stack, a gate contact pattern that is electrically connected to the peripheral circuit region and formed through the gate stack in the connection region, a dummy pattern penetrating the gate stack and being insulated from the peripheral circuit region and the gate electrodes, and a set of insulating patterns adjacent to the gate contact pattern and the dummy pattern. The set of insulating patterns includes first insulating patterns positioned along circumferences of spaces in which the set of insulating patterns are formed, each insulating pattern of the first insulating patterns having a recess, second insulating patterns each positioned in a corresponding one of recesses of the first insulating patterns, and third insulating patterns each filling a corresponding one of the spaces in which the set of insulating patterns are formed. The first insulating patterns include first and second subsets of the first insulating patterns, each insulating pattern of the first subset of insulating patterns is positioned between a corresponding one of the gate electrodes and the gate contact pattern, and each insulating pattern of the second subset of insulating patterns is positioned between a corresponding one of the gate electrodes and the dummy pattern. The second insulating patterns include third and fourth subsets of the second insulating patterns, each insulating pattern of the third subset of insulating patterns is positioned between a corresponding one of the gate electrodes and the gate contact pattern, and each insulating pattern of the fourth subset of insulating patterns is positioned between a corresponding one of the gate electrodes and the dummy pattern. The third insulating patterns include fifth and sixth subsets of the third insulating patterns, each insulating pattern of the fifth subset of insulating patterns is positioned between a corresponding one of the gate electrodes and the gate contact pattern, and each insulating pattern of the sixth subset of insulating patterns is positioned between a corresponding one of the gate electrodes and the dummy pattern. The set of insulating patterns are interposed between the dummy pattern and the gate electrodes, the gate electrodes include a connection gate electrode and remaining gate electrodes, the gate contact pattern is electrically connected to the connection gate electrode and is insulated from the remaining gate electrodes by the set of insulating patterns, the third insulating patterns include SiN (silicon nitride), and a horizontal thickness of each insulating pattern of the fifth subset of insulating patterns in a direction parallel to the substrate is thicker than a horizontal thickness of each insulating pattern of the sixth subset of insulating patterns in the direction parallel to the substrate in a cross sectional view.

A semiconductor device according to another embodiment includes a substrate including a peripheral circuit region; and a cell region positioned adjacent to the peripheral circuit region and including a cell array region and a connection region. The cell region includes a gate stack including interlayer insulating layers and gate electrodes alternately stacked on the substrate, a channel pattern positioned in the cell array region and penetrating the gate stack, a gate contact pattern that is electrically connected to the peripheral circuit region and formed through the gate stack in the connection region, and a dummy pattern penetrating the gate stack and being insulated from the peripheral circuit region and the gate electrodes. A set of insulating patterns is in contact with the gate contact pattern, the gate contact pattern includes SiN, the set of insulating patterns include a first group of insulating patterns and a second group of insulating patterns, first group of insulating patterns are interposed between the dummy pattern and the gate electrodes, the gate electrodes include a connection gate electrode and remaining gate electrodes, the gate contact pattern is electrically connected to the connection gate electrode and is insulated from the remaining gate electrodes by the set of insulating patterns, and the second group of insulating patterns are in contact with the dummy pattern and do not include SiN.

An electronic system according to an embodiment includes a main substrate, a semiconductor device on the main substrate, and a controller electrically connected to the semiconductor device on the main substrate. The semiconductor device includes a substrate including a peripheral circuit region, and a cell region positioned adjacent to the peripheral circuit region and including a cell array region and a connection region. The cell region includes a gate stack including interlayer insulating layers and gate electrodes alternately stacked on the substrate, a channel pattern positioned in the cell array region and penetrating the gate stack, a gate contact pattern that is electrically connected to the peripheral circuit region through the gate stack in the connection region, a dummy pattern penetrating the gate stack and being insulated from the peripheral circuit region and the gate electrodes, and a set of insulating patterns adjacent to the gate contact pattern and the dummy pattern. The set of insulating patterns include first insulating patterns positioned along circumferences of spaces in which the set of insulating patterns are formed, each of the first insulating patterns having a recess, second insulating patterns each positioned in a corresponding one of recesses of the first insulating patterns, and third insulating patterns each filling a corresponding one of the spaces in which the set of insulating patterns are formed. The first insulating patterns include first and second subsets of the first insulating patterns, each insulating pattern of the first subset of insulating patterns is positioned between a corresponding one of the gate electrodes and the gate contact pattern, and each insulating pattern of the second subset of insulating patterns is positioned between a corresponding one of the gate electrodes and the dummy pattern. The second insulating patterns include third and fourth subsets of the second insulating patterns, each insulating pattern of the third subset of insulating patterns is positioned between a corresponding one of the gate electrodes and the gate contact pattern, and each insulating pattern of the fourth subset of insulating patterns is positioned between a corresponding one of the gate electrodes and the dummy pattern. The third insulating patterns include fifth and sixth subsets of the third insulating patterns, each insulating pattern of the fifth subset of insulating patterns is positioned between a corresponding one of the gate electrodes and the gate contact pattern, and each insulating pattern of the sixth subset of insulating patterns is positioned between a corresponding one of the gate electrodes and the dummy pattern. The set of insulating patterns is interposed between the dummy pattern and the gate electrodes, the gate electrodes include a connection gate electrode and remaining gate electrodes, the gate contact pattern is electrically connected to the connection gate electrode and is insulated from the remaining gate electrodes by the set of insulating patterns, the third insulating patterns include SiN, and a horizontal thickness of each insulating pattern of the fifth subset of insulating patterns in a direction parallel to the substrate is thicker than a horizontal thickness of each insulating pattern of the sixth subset of insulating patterns in the direction parallel to the substrate in a cross sectional view.

A manufacturing method of a semiconductor device according to an embodiment includes forming a stacking structure by alternately stacking a plurality of sacrificial insulation layers and a plurality of insulation layers on a circuit region including a peripheral circuit structure, simultaneously forming a channel penetration hole, a gate contact part penetration hole, and a dummy penetration hole in the stacking structure, etching the sacrificial insulation layer in contact with the gate contact part penetration hole and the dummy penetration hole, forming a first insulating pattern, a second insulating pattern, and a third insulating pattern in a space where the sacrificial insulation layer is etched, etching a third insulating pattern in the dummy penetration hole, and etching the third insulating pattern in the dummy penetration hole, wherein the third insulating pattern includes SiN.

A semiconductor device according to another embodiment includes a substrate including a peripheral circuit region; and a cell region positioned adjacent to the peripheral circuit region and including a cell array region and a connection region. The cell region includes a gate stack including interlayer insulating layers and gate electrodes alternately stacked on the substrate, a channel pattern positioned in the cell array region and penetrating the gate stack, a gate contact pattern that is electrically connected to the peripheral circuit region and formed through the gate stack in the connection region, and a dummy pattern penetrating the gate stack and being insulated from the peripheral circuit region and the gate electrodes. A set of insulating patterns is in contact with the gate contact pattern, the set of insulating patterns include a first group of insulating patterns and a second group of insulating patterns, the first group of insulating patterns are interposed between the dummy pattern and the gate electrodes, the gate electrodes include a connection gate electrode and remaining gate electrodes, the gate contact pattern is electrically connected to the connection gate electrode and is insulated from the remaining gate electrodes by the set of insulating patterns, the second group of insulating patterns are in contact with the dummy pattern, and the gate contact pattern includes more nitrogen per unit volume than the second group of insulating patterns.

According to an embodiment, the semiconductor device with improved reliability and the electronic system including the semiconductor device are provided.

### BRIEF DESCRIPTION OF THE DRAWINGS

FIG. 1 is a partial top plan view illustrating a semiconductor device according to an embodiment.

FIG. 2 is a partial cross-sectional view of a semiconductor device taken along lines A-A′ and B-B′ of FIG. 1.

FIG. 3 is a partial cross-sectional view showing an example of a channel structure included in a semiconductor device illustrated in FIG. 1.

FIG. 4 is an enlarged view of a region indicated by C in FIG. 2.

FIG. 5 is an enlarged view of a region indicated by D in FIG. 2.

FIG. 6 is a view illustrating the same region as FIG. 4 for another embodiment.

FIG. 7 is a view illustrating the same region as FIG. 5 for another embodiment.

FIG. 8 is a view simply illustrating a cross-section of a gate contact part and a dummy structure in an embodiment.

FIG. 9 is a view simply illustrating a cross-section of a gate contact part and a dummy structure.

FIG. 10 is a three-dimensional view of a formation region of a dummy structure.

FIG. 11 to FIG. 16 are views illustrating a forming process of an embodiment of a dummy structure.

FIG. 17 to FIG. 21 are views illustrating a forming process of another embodiment of a dummy structure.

FIG. 22 to FIG. 41 are views illustrating a manufacturing process of a semiconductor device according to an embodiment.

FIG. 42 is a schematic view of an electronic system including a semiconductor device according to an embodiment.

FIG. 43 is a perspective view schematically illustrating an electronic system including a semiconductor device according to an embodiment.

FIG. 44 is a perspective view schematically illustrating an electronic system.

FIGS. 45 and 46 are cross-sectional views schematically showing semiconductor packages, according to embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clarify the present disclosure, parts that are not directly related to the description may be omitted, and the same or equivalent elements may be denoted by the same or similar reference numerals or symbols throughout the specification.

Further, since sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, the thicknesses of some layers and regions are excessively displayed.

It will be understood that when an element such as a layer, film, region, or substrate is referred to as being “connected” or “coupled” to or “on” another element, it can be directly on the other element or intervening elements may also be present. In contrast, when an element is referred to as being “directly connected” or “coupled to” or “directly on” another element, there are no intervening elements present (at least at the point of contact). Further, in the specification, the word “on” may mean positioned above or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements. Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Further, in this specification, the phrase “in a plan view” means viewing a target portion from the top, and the phrase “in a cross sectional view” (or in a cross-section) means viewing a vertical cross-section of a target portion from the side, unless context indicates otherwise. For example, items described as being viewed as a horizontal cross-section describe a cross-section of a target portion viewed from a top-down view.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

A semiconductor device and a manufacturing method thereof according to various embodiments are explained below with reference to accompanying drawings.

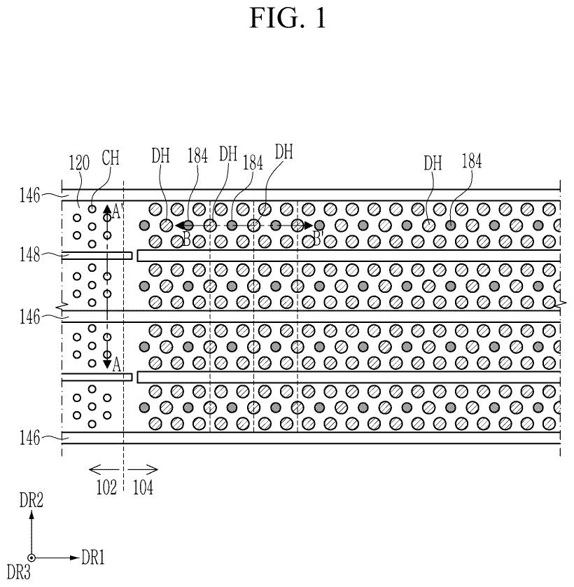

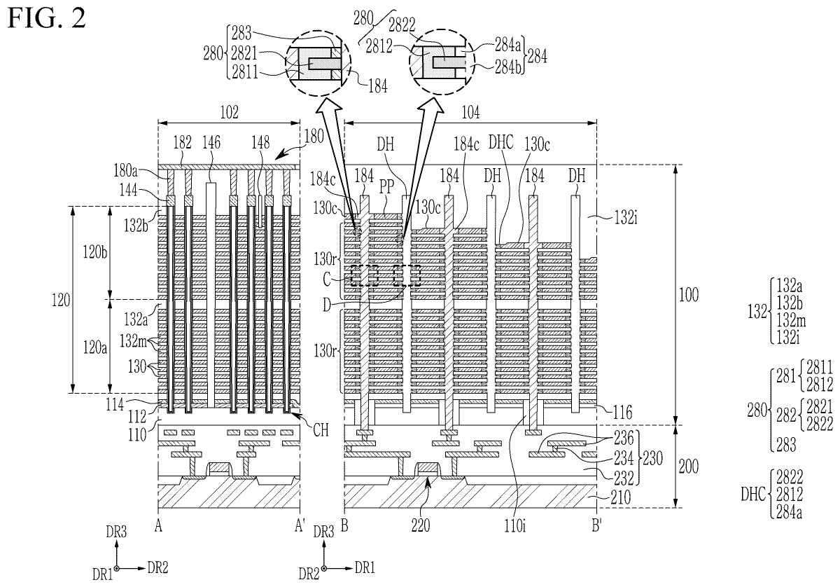

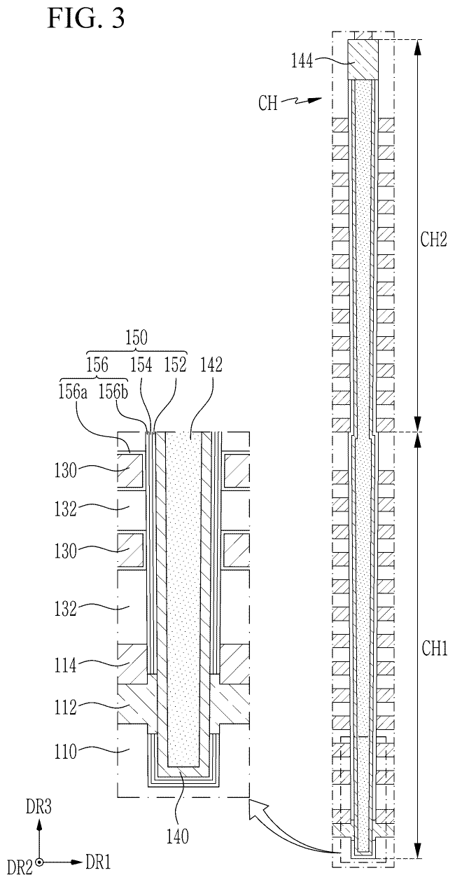

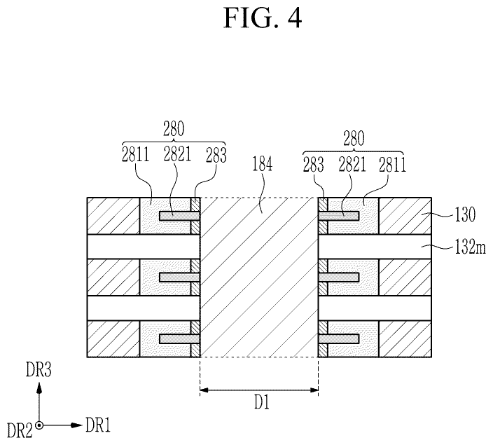

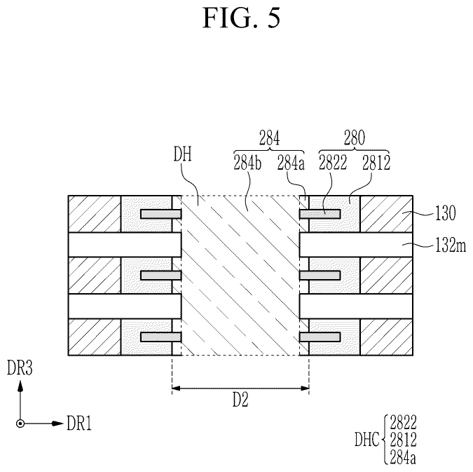

FIG. 1 is a partial top plan view illustrating a semiconductor device according to an embodiment. FIG. 2 is a partial cross-sectional view of a semiconductor device taken along lines A-A′ and B-B′ of FIG. 1. FIG. 3 is a partial cross-sectional view showing an example of a channel structure included in a semiconductor device illustrated in FIG. 1. FIG. 4 is an enlarged view of a region indicated by C in FIG. 2. FIG. 5 is an enlarged view of a region indicated by D in FIG. 2.

For the sake of simplicity and clear understanding, FIG. 1 mainly shows a channel structure (or a channel pattern) CH, a gate contact part (a gate contact pattern) 184, etc. In FIG. 1, a dotted line indicates where a step difference of a gate stacking structure (or a gate stack) is formed in the cross-sectional view of FIG. 2. For example, a plurality of dummy patterns DH (described later) may be disposed along the dotted line indicated in the plan view. In FIG. 1, for better comprehension and ease of description, the dotted line is drawn only in some regions. However, the dotted lines indicating the step difference of the gate stack may be arranged repeatedly in a first direction DR1 throughout a connection region 104.

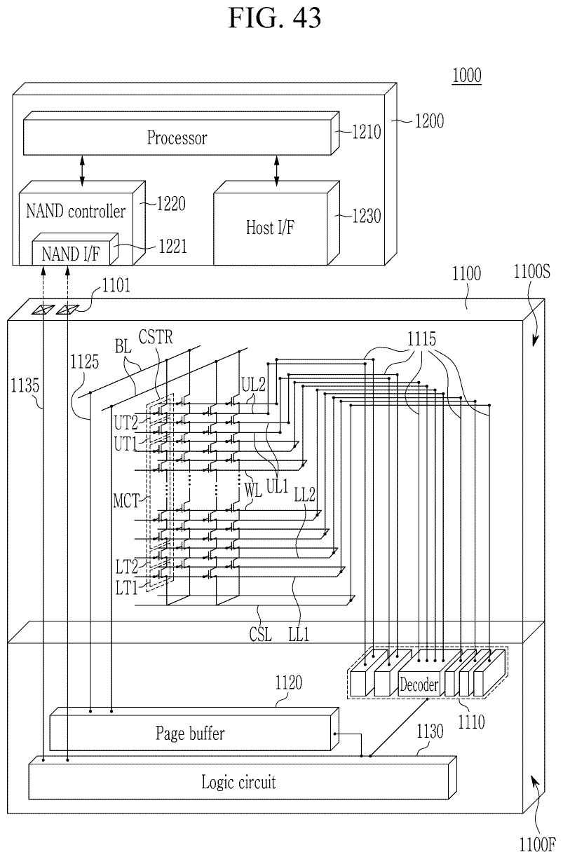

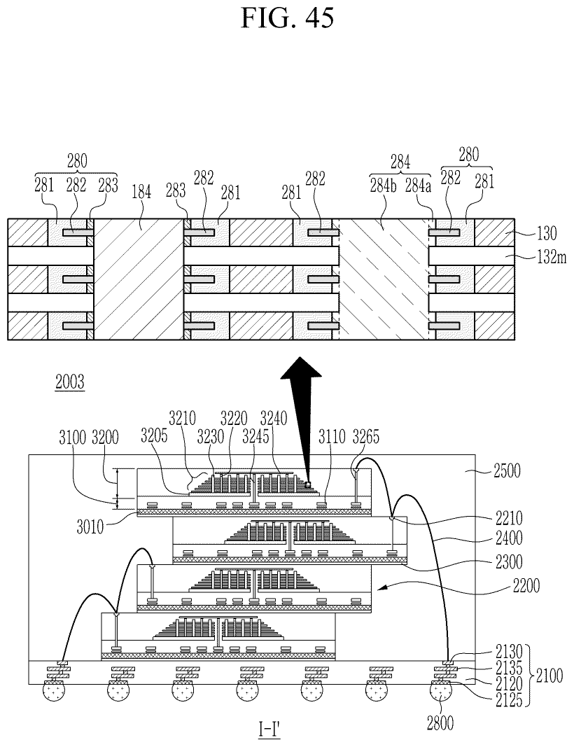

Referring to FIG. 1 to FIG. 3, a semiconductor device according to an embodiment may include a cell region 100 having a memory cell structure and a circuit region (or a peripheral circuit region) 200 having a peripheral circuit structure that controls the operation of the memory cell structure. For example, the circuit region 200 and the cell region 100 may be portions corresponding to a first structure 1100F and a second structure 1100S of the semiconductor device 1100 included in an electronic system 1000 illustrated in FIG. 43, respectively. Alternatively, the circuit region 200 and the cell region 100 may correspond to the first structure 3100 and the second structure 3200 of the semiconductor chip 2200 illustrated in FIG. 45.

Here, the circuit region 200 may include a peripheral circuit structure formed on a first substrate 210, and the cell region 100 may include a gate stacking structure 120 and a channel structure CH formed on the cell array region 102 of a second substrate 110 as a memory cell structure. A first wire part 230 may be provided in the circuit region 200, and a second wire part (not shown) electrically connected to the memory cell structure may be provided in the cell region 100.

In an exemplary embodiment, the cell region 100 may be positioned on the circuit region 200. Accordingly, the region corresponding to the circuit region 200 does not need to be secured separately from the cell region 100 such that the circuit region 200 and the cell region 100 vertically overlap each other, so the region of the semiconductor device may be reduced. However, the embodiment is not limited to this, and the circuit region 200 may be positioned next to the cell region 100 (e.g., in the first direction DR1). Numerous other variations are possible.

The circuit region 200 may include the first substrate 210, and a circuit element 220 and the first wire part 230 formed on the first substrate 210.

The first substrate 210 may be a semiconductor substrate including a semiconductor material. For example, the first substrate 210 may be a semiconductor substrate made of a semiconductor material, or may be a semiconductor substrate in which a semiconductor layer is formed on a base substrate. For example, the first substrate 210 may be composed of a monocrystalline or a polycrystalline silicon, an epitaxial silicon, a germanium, silicon-germanium, a silicon on insulator (SOI), or a germanium on insulator (GOI).

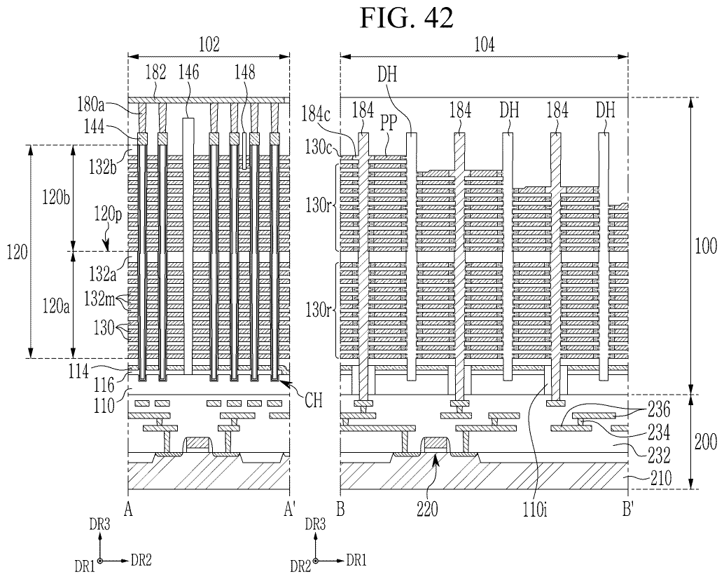

The circuit element 220 formed on the first substrate 210 may include various circuit elements that control the operation of the memory cell structure provided in the cell region 100. For example, the circuit elements 220 may constitute a peripheral circuit structure including, for example, a decoder circuit (a reference numeral 1110 of FIG. 43), a page buffer (a reference numeral 1120 of FIG. 43), and a logic circuit (a reference numeral 1130 of FIG. 42).

The circuit elements 220 may include, for example, a transistor, but is not limited thereto. For example, the peripheral circuit elements 220 may include not only active elements such as transistors, but also passive elements such as capacitors, resistors, and inductors.

The first wire part 230 positioned on the first substrate 210 may be electrically connected to the circuit element 220. In an exemplary embodiment, the first wire part 230 may include a plurality of wiring layers 236 spaced apart with (e.g., by) a first insulation layer 232 and connected to form a desired path by contact vias 234. The wiring layer 236 or the contact via 234 may include various conductive materials, and the first insulation layer 232 may include various insulating materials. For example, among the plurality of wiring layers 236, the wiring layer 236 positioned at the uppermost part adjacent to cell region 100 may have a pad portion to which the gate contact part 184, etc. is connected, or may form a pad portion which may be subject to a wire bonding process.

The cell region 100 may include the cell array region 102 and the connection region 104. The gate stacking structure 120 and the channel structure CH may be formed on the second substrate 110 in the cell array region 102. In the cell array region 102 and/or the connection region 104, a structure for connecting the gate stacking structure 120 and/or the channel structure CH formed in the cell array region 102 to the circuit region 200 or an external circuit may be positioned.

In an embodiment, the second substrate 110 may include a semiconductor layer including a semiconductor material. For example, the second substrate 110 may include a semiconductor layer made of a semiconductor material, or may include a semiconductor layer positioned on a base substrate. For example, the second substrate 110 may be composed of silicon, germanium, silicon-germanium, silicon-on-insulator, or germanium-on-insulator. Here, the semiconductor layer included in the second substrate 110 may be doped with p-type or n-type impurities, for example, n-type impurities (e.g., phosphorus (P), arsenic (As), etc.) may be doped. A substrate insulating part 110i may be provided in the region through which the gate contact part 184 passes in the second substrate 110. However, the embodiment is not limited to the material of the second substrate 110, the conductivity type of the impurity doped in the semiconductor layer, or the material thereof.

In the cell array region 102, a gate stacking structure 120 including the cell insulation layers 132 and the gate electrodes 130 alternately stacked on one surface (e.g., a front surface or an upper surface) of the second substrate 110, and the channel structure CH extending in a direction crossing the second substrate 110 (in a direction perpendicular to upper surface of the second substrate 110) through the gate stacking structure 120 may be provided.

In an exemplary embodiment, horizontal conductive layers 112 and 114 may be provided between the second substrate 110 and the gate stacking structure 120 in the cell array region 102. The horizontal conductive layers 112 and 114 may serve to electrically connect the channel structure CH and the second substrate 110. For example, the horizontal conductive layers 112 and 114 may include a first horizontal conductive layer 112 positioned on one surface of the second substrate 110, and may further include a second horizontal conductive layer 114 positioned on the first horizontal conductive layer 112. In some regions of the connection region 104, the first horizontal conductive layer 112 may not be provided between the second substrate 110 and the gate stacking structure 120. Instead of the first horizontal conductive layer 112, a horizontal insulation layer 116 may be provided between the second substrate 110 and the gate stacking structure 120. For example, during the manufacturing process, a portion of the horizontal insulation layer 116 may be replaced by the first horizontal conductive layer 112 in the connection region 104, while another portion of the horizontal insulation layer 116 may remain in the cell region 100.

The first horizontal conductive layer 112 may function as a part of a common source line of the semiconductor device. For example, the first horizontal conductive layer 112 may function as the common source line with the second substrate 110. As shown in the enlarged view of FIG. 3, the channel structure CH extends through the horizontal conductive layers 112 and 114 to reach the second substrate 110, and the gate dielectric layer 150 is removed at the position where the first horizontal conductive layer 112 is positioned, so that the first horizontal conductive layer 112 may be directly connected to the channel layer 140 at the circumference of the channel layer 140.

The first and second horizontal conductive layers 112 and 114 may include a semiconductor material (e.g., polycrystalline silicon). For example, the first horizontal conductive layer 112 may be an impurity-doped polycrystalline silicon layer, and the second horizontal conductive layer 114 may be an impurity-doped polycrystalline silicon layer or a layer including an impurity diffused from the first horizontal conductive layer 112. However, the embodiment is not limited to this and the second horizontal conductive layer 114 may be composed of an insulating material. Alternatively, the second horizontal conductive layer 114 may not be provided.

A gate stacking structure 120 in which the cell insulation layers 132 and the gate electrodes 130 are alternately stacked may be positioned on the second substrate 110 (for example, on the first and second horizontal conductive layers 112 and 114 formed on the second substrate 110).

In an exemplary embodiment, the gate stacking structure 120 may include a plurality of sub-stacking structures 120a and 120b sequentially stacked on the second substrate 110. Therefore, the number of the stacked gate electrodes 130 may be increased, maximizing the number of the memory cells. By employing the plurality of sub-stacking structures 120a and 120b, the overall modification to the device configuration may be minimized while increasing the data storage capacity. For example, the gate stacking structure 120 may simplify the structure while increasing the data storage capacity by including the sub-stacking structures (first and second gate stacking structures) 120a and 120b. However, the embodiment is not limited to this, and the gate stacking structure 120 may be composed of three or more sub-stacking structures or may be a single sub-stacking structure.

In the gate stacking structure 120, the gate electrode 130 may include a lower gate electrode, a memory cell gate electrode, and an upper gate electrode sequentially positioned from the second substrate 110. The lower gate electrode may be used as a gate electrode of a ground selection transistor, the memory cell gate electrode may form the memory cell, and the upper gate electrode may be used as a gate electrode of a string selection transistor. The number of the memory cell gate electrodes may be determined depending on the data storage capacity of the semiconductor device. According to an embodiment, the lower gate electrode and the upper gate electrode may each be provided in plural (e.g., two, or more), and may have substantially the same structure as the memory cell gate electrode or a different structure. Also, a part of the gate electrodes 130, for example, the memory cell gate electrodes adjacent to the lower gate electrode and the upper gate electrode, may be a dummy gate electrode.

The cell insulation layer 132 may include an interlayer insulating layer 132m positioned between two adjacent gate electrodes 130 within the first and second gate stacking structures 120a and 120b, and an upper insulation layer 132a and 132b positioned on the first and second gate stacking structures 120a and 120b. Also, it may further include a pad insulating part 132i formed in the connection region 104. In an embodiment, the pad insulating part 132i may be a part of the upper insulation layers 132a and/or 132b, or may be provided separately from the upper insulation layers 132a and 132b.

For example, the upper insulation layers 132a and 132b may include first and second upper insulation layers 132a and 132b positioned on the first and second gate stacking structures 120a and 120b, respectively. At this time, the first upper insulation layer 132a may be an intermediate insulation layer positioned between the adjacent first and second gate stacking structures 120a and 120b, and the second upper insulation layer 132b may be an uppermost insulation layer positioned at the gate stacking structure 120. The second upper insulation layer 132b may partially or entirely cover the cell region 100. For example, the second upper insulation layer 132b may constitute a part or all of the cell region insulation layer positioned entirely above the cell region 100.

In the embodiment, the thicknesses of the plurality of cell insulation layers 132 may not all be the same. For example, the thickness of the upper insulation layers 132a and 132b may be greater than the thickness of the interlayer insulating layer 132m. However, the shape, structure, etc. of the cell insulation layer 132 may be modified in various ways according to an embodiment.

The gate electrode 130 may include various conductive materials. For example, the gate electrode 130 may include a metal material such as tungsten (W), copper (Cu), aluminum (Al), polycrystalline silicon, a metal nitride (e.g., titanium nitride (TiN), tantalum nitride (TaN)), or a combination thereof. As shown in the enlarged view of FIG. 3, a part of a blocking layer 156 (e.g., a first blocking layer 156a) composed of an insulating material may be positioned on the outside of the gate electrode 130. For example, the first blocking layer 156a may surround the gate electrode 130. The cell insulation layer 132 may include various insulating materials. For example, the cell insulation layer 132 may include silicon oxide, silicon nitride, silicon oxynitride, a low dielectric constant material having a lower permittivity than silicon oxide, or a combination thereof.

In an embodiment, the channel structure CH that extends in a third direction (DR3, for example, a vertical direction perpendicular to the second substrate 110) penetrating through the gate stacking structure 120 and intersecting (e.g., protruding into or partly penetrating into) the second substrate 110 may be formed.

The channel structure CH may include a channel layer 140 and a part of a gate dielectric layer 150 positioned on the channel layer 140 between the gate electrode 130 and the channel layer 140. For example, the channel structure CH may include a second blocking layer 156b, a charge storage layer 154 and a tunneling layer 152 which are described later. The channel structure CH may further include a core insulation layer 142 positioned inside the channel layer 140, and may further include a channel pad 144 positioned on the channel layer 140 and/or the gate dielectric layer 150.

Each channel structure CH may form one memory cell string, and the plurality of channel structures CH may be arranged spaced apart from each other in a plan view, while forming rows and columns. For example, the plurality of channel structures CH may be arranged in various shapes, such as a lattice shape or a zigzag shape, in a plan view. The channel structure CH may have a columnar shape. For example, the channel structure CH may have an inclined side surface so that the width becomes narrower as it approaches the second substrate 110, according to (e.g., depending on) the aspect ratio, when viewed in a cross-section. However, the embodiment is not limited to this, and the arrangement, structure, shape, etc. of the channel structure CH may be variously modified.

A core insulation layer 142 may be provided in the central region of the channel structure CH, and the channel layer 140 may be formed by surrounding the side wall of the core insulation layer 142. For example, the core insulation layer 142 may have a columnar shape (e.g., a circular cylinder shape or a polygonal column shape), and the channel layer 140 may have a planar shape such as a cyclic (annular) shape. However, the embodiment is not limited to this. In some embodiments, the core insulation layer 142 may not be provided and the channel layer 140 may have a columnar shape (e.g., a circular cylinder shape or a polygonal column shape).

The channel layer 140 may include a semiconductor material, for example, polycrystalline silicon. The core insulation layer 142 may include various insulating materials. For example, the core insulation layer 142 may include silicon oxide, silicon nitride, silicon oxynitride, or combination thereof. However, the embodiment is not limited to the materials of the channel layer 140 and the core insulation layer 142.

The gate dielectric layer 150 positioned between the gate electrode 130 and the channel layer 140 may include a tunneling layer 152, a charge storage layer 154, and a blocking layer 156 sequentially formed on the channel layer 140.

At this time, the tunneling layer 152 is a layer in (e.g., through) which charges are tunneled according to a voltage applied to the gate electrode 130, and may include an insulating material, and may be configured to induce charge tunneling therethrough (e.g., capable of a charge tunneling). The tunneling layer 152 may include a material such as silicon oxide or silicon oxynitride, and for example, may be formed by stacking a silicon oxide layer and a silicon nitride layer.

The charge storage layer 154, located between the tunneling layer 152 and the blocking layer 156, may be used as a data storage region. For example, the charge storage layer 154 may be configured to function as a charge trapping layer (e.g., capable of a charge trap), and may be formed of, for example, a silicon nitride layer. When the charge storage layer 154 is composed of silicon nitride, it exhibits a superior retention and offers better integration advantage compared to when it is composed of polycrystalline silicon. However, the embodiment is not limited to the material of the charge storage layer 154.

The blocking layer 156 may be placed between the charge storage layer 154 and the gate electrode 130. The blocking layer 156 may include an insulating material that may prevent an undesirable inflow of charges into the gate electrode 130. For example, the blocking layer 156 may include silicon oxide, silicon nitride, silicon oxynitride, a high dielectric constant material or a combination thereof. Here, high dielectric constant material means a dielectric material with higher permittivity than silicon oxide. The high dielectric constant material, for example, may include aluminum oxide (Al₂O₃), tantalum oxide (Ta₂O₃), titanium oxide (TiO₂), yttrium oxide (Y₂O₃) zirconium oxide (ZrO₂), zirconium silicon oxide (ZrSiₓO_{y}), hafnium oxide (HfO₂) hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃) or combinations thereof.

In an embodiment, the blocking layer 156 may include a first blocking layer 156a including a portion extending horizontally along the gate electrode 130, and a second blocking layer 156b extending vertically between the first blocking layer 156a and the charge storage layer 154.

A channel pad 144 may be placed on the channel layer 140 and/or the gate dielectric layer 150. The channel pad 144 may be arranged to cover the upper surface of the core insulation layer 142 and be electrically connected to the channel layer 140. The channel pad 144 may include a conductive material, for example, an impurity-doped polycrystalline silicon, but is not limited thereto.

When the plurality of gate stacking structures 120a and 120b are provided as described above, the channel structure CH may have a plurality of channel structures CH1 and CH2 penetrating the plurality of gate stacking structures 120a and 120b, respectively. In an embodiment, the plurality of channel structures CH may include first and second channel structures CH1 and CH2 extending through the first and second gate stacking structures 120a and 120b, respectively.

The first and second channel structures CH1 and CH2 may be connected to each other. The first and second channel structures CH1 and CH2 may have inclined side surfaces such that their widths become narrower as they approach the second substrate 110, depending on the aspect ratio when viewed in cross-section. As shown in FIG. 3, a curved portion may be provided due to a difference in the width at the connection portion between the first channel structure CH1 and the second channel structure CH2. As another example, the first and second channel structures CH1 and CH2 may have inclined side surfaces that are continuously connected without any curved portion. Thus, the embodiment is not limited to the forms of the first and second channel structures CH1 and CH2.

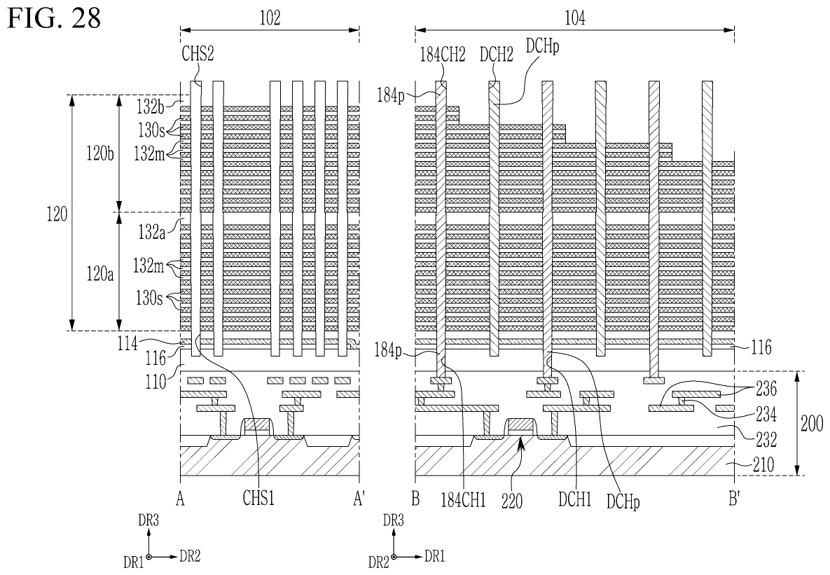

FIG. 3 illustrates an integral structure of the gate dielectric layer 150, the channel layer 140, and the core insulation layer 142 of the first and second channel structures CH1 and CH2. For example, the gate dielectric layer 150 of the first channel structure CH1 may be continuously formed with the gate dielectric layer 150 of the second channel CH2. Each of the channel layer 140 and the core insulation layer 142 may also be formed by the continuous manner. As described with reference to FIG. 28, after forming first and second channel penetration holes CHS1 and CHS2 for the first and second channel structures CH1 and CH2, the gate dielectric layer 150, the channel layer 140, and the core insulation layer 142 may be formed over the entire first and second channel penetration holes CHS1 and CHS2 to form the above-described structure. However, the embodiment is not limited thereto. As another example, each of the gate dielectric layer 150, the channel layer 140, and the core insulation layer 142 of the first channel structure CH1 may be formed separately from a corresponding one of those of the second channel structure CH2, and electrically connected to each other. For example, during a first process step, after forming a first channel penetration hole CHS1 for the first channel structure CH1, the gate dielectric layer 150, the channel layer 140, and the core insulation layer 142 may be formed in the first channel penetration hole CHS1. During a second process step, after forming a second channel penetration hole CHS1 for the second channel structure CH2, the gate dielectric layer 150, the channel layer 140, and the core insulation layer 142 may be formed in the second channel penetration hole CHS2. Numerous other variations are possible.

In an exemplary embodiment, the channel pad 144 may be provided on the channel structure CH (e.g., the second channel structure CH2) provided on the gate stacking structure 120 (e.g., the second gate stacking structure 120b) positioned at the upper end position in the plurality of gate stacking structures 120. Alternatively, the channel pad 144 may be provided on the first and second channel structures CH1 and CH2, respectively. In this case, a lower channel pad 144 of the first channel structure CH1 may be connected to an upper channel layer 140 of the second channel structure CH2.

In an embodiment, the gate stacking structure 120 may be partitioned into multiple parts in a plan view by separation structures 146 extending in the third direction DR3 intersecting the upper surface of the second substrate 110. The separation structures 146 may be formed to penetrate the gate stacking structure 120.

For example, the separation structure 146 may extend through the gate electrode 130 and the cell insulation layer 132 to the second substrate 110. In a plan view, the separation structure 146 may be provided in multiples so as to extend in the first direction DR1 and be spaced apart from each other by a predetermined distance in the second direction DR2 intersecting the first direction DR2. Accordingly, in a plan view, the plurality of gate stacking structures 120 may each extend in the first direction DR1 and be spaced apart from each other by a predetermined interval in the second direction DR2. The gate stacking structure 120 partitioned by the separation structures 146 may form one memory cell block. However, the embodiment is not limited to this, and the range of the memory cell blocks is not limited thereto.

For example, the separation structure 146 may have a slanted side surface with the width that decreases toward the second substrate 110 when viewed in the cross-section due to the high aspect ratio. However, the embodiment is not limited to this and the side of the separation structure 146 may be perpendicular to the second substrate 110. FIG. 2 illustrates that the separation structure 146 has the continuous sloped side surface without an irregularity in the cross-section of the first and second gate stacking structures 120a and 120b. However, the embodiment is not limited thereto. For example, the separation structure 146 may have a folding portion or a bent portion at the interface between the first and second gate stacking structures 120a and 120b.

The separation structure 146 may be filled with various insulating materials. For example, the separation structure 146 may include an insulating material such as silicon oxide, silicon nitride, or silicon oxynitride. However, the embodiment is not limited to this, and the structure, shape, material, etc. of the separation structure 146 may be modified in various ways.

Also, an upper separation region 148 may be formed on the upper side of the gate stacking structure 120.

In a plan view, the upper separation region 148 extends in the first direction DR1 and may be provided in multiples spaced apart from each other with a predetermined interval in the second direction DR2 intersecting the first direction DR1.

The upper separation region 148 may be formed by penetrating one or a plurality of gate electrodes 130 including the upper gate electrode positioned between the separation structures 146. The upper separation region 148 may, for example, separate three gate electrodes 130 from each other in the second direction DR2. However, the embodiment is not limited to the number of the gate electrodes 130 separated by the upper separation region 148. The upper separation region 148 may have a form filled with an insulating material. For example, the upper separation region 148 may be formed by penetrating the uppermost gate electrode (or a plurality of gate electrodes 130 including the uppermost gate electrode). The upper separation region 148 may be positioned between the separation structures 146. Though the upper separation region 148 is described as separating the two topmost gate electrodes 130 into plural in the second direction DR2, the invention is not limited thereto. For example, the number of the gate electrodes 130 separated by the upper separation region 148 may be one or more than two. The upper separation region 148 may be formed of an insulating material. For example, the upper separation region 148 may include an insulating material such as silicon oxide, silicon nitride, or silicon oxynitride. However, the embodiment is not limited to this, and the structure, shape, material, etc. of the upper separation region 148 may be modified in various ways.

A connection region 104 and a second wire part (or wiring pattern) 180 may be provided to connect the gate stacking structure 120 and the channel structure CH provided in the cell array region 102 to the circuit region 200 or an external circuit.

Here, the second wire part 180 may include all members (connection components) that electrically connect each of the gate electrode 130, the channel structure CH, the horizontal conductive layer 112 and 114 and/or the second substrate 110 to the circuit region 200 or the external circuit. For example, the second wire part 180 may include a bit line 182, a gate contact part 184, and a contact via 180a connected to each, and wire patterns (not shown) connecting them. Although not shown, in a source contact part, a penetration plug and a connecting wire, the like may be positioned in the connection region 104.

The bit line 182 may be positioned on the cell insulation layer 132 of the gate stacking structure 120 formed in the cell array region 102. The bit line 182 may be extended to the second direction DR2, which intersects the direction in which the gate electrode 130 is extended. The bit line 182 may be electrically connected to the channel structure CH, for example, through the channel pad 144 and the via contact via 180a (bit line contact via).

The connection region 104 may be placed around the cell array region 102 in a plan view, and a part of the second wire part 180 may be positioned in the connection region 104. The connection region 104 may be provided with members (components) for the connection to the gate electrode 130, the horizontal conductive layer 112 and 114 and/or the second substrate 110, and the circuit region 200. In addition, the connection region 104 may include a portion where input/output pads and input/output connection wires are formed.

In further detail, the gate contact part 184 may penetrate the gate stacking structure 120 and be electrically connected to a portion of the gate electrodes 130, and extend to pad portions provided in the circuit region 200 to be electrically connected to the circuit region 200. For example, a selected gate contact part 184 may be electrically connected to the topmost one of a corresponding set of the gate electrodes 130, through which the selected gate contact part 184 penetrates. The connection structure of the gate contact part 184 and the gate electrode 130 will be described in more detail later.

A dummy structure DH may be provided in the connection region 104. The dummy structure DH may play a role in reducing the stress that may be applied to the gate stacking structure 120. It may have the same or similar structure or shape as the channel structure CH, but is not electrically connected to the bit line 182. The dummy structure DH may be formed together with the channel structure CH in the same process step and may be composed of substantially the same structure, shape, material, etc., or may be formed in different process steps from the channel structure CH and may have a different structure, shape, material, etc. from the channel structure CH. In an exemplary embodiment, the dummy structure DH may have a larger planar size than the channel structure CH.

As used herein, the term “dummy” is used to refer to a component that has the same or similar structure and shape as other components but does not have a substantial electrical function (e.g., to convey information) during the operation of the semiconductor device. In some instances, a “dummy” element may be electrically floated, or may be connected to various voltage sources but otherwise not provide substantially the same functionality of the non-dummy element.

The terms planar shape, planar size, planar diameter, horizontal thickness and similar terms refer to the corresponding features in the lateral cross-section of a semiconductor device, extending in directions parallel to the major surfaces of the substrate 110. Unless otherwise specified, comparisons of these terms are made within such a lateral cross-section. For example, when the planar diameter of A is stated to be greater than that of B, it means that A's diameter exceeds B's within the same lateral cross-sectional plane.

The terms vertically, vertical position, vertical thickness and similar terms may be used to refer to the corresponding features in the vertical cross-section of a semiconductor device, extending in directions perpendicular to the major surfaces of the substrate 110, unless otherwise specified.

In an embodiment, the formation of the penetration holes for forming the channel structure CH, the gate contact part 184, and the dummy structure DH may be accomplished by the same process. As will be explained separately later, the process may be simplified by simultaneously forming penetration holes of the channel structure CH, gate contact part 184, and dummy structure DH. After the simultaneous formation of the penetration holes, an expansion process may be performed on the penetration holes for the gate contact part 184 and the dummy structure DH. Therefore, the planar size of the gate contact part 184 and the dummy structure DH may be larger than the planar size of the channel structure CH. In an embodiment, the planar diameter of the gate contact part 184 and the dummy structure DH may be larger than the planar diameter of the channel structure CH by 10% to 15%. However, this is an example and the present invention is not limited to this.

By using the selected gate contact part 184, the topmost one of a corresponding set of the gate electrodes 130 may be electrically connected to the circuit element 220 of the circuit region 200. In a similar way, the bit line 182, the horizontal conductive layer 112 and 114 and/or the second substrate 110 connected to the channel structure CH may be electrically connected to the circuit element 220 of the circuit region 200 by the second wire part 180 (including the gate contact part 184) and the first wire part 230.

FIG. 2 illustrates that the gate contact part 184 has the inclined side surface so that the width becomes narrower as it approaches the second substrate 110 according to the aspect ratio when viewed in the cross-section, and that the irregularity (e.g., curved portion) is provided at the boundary of the plurality of gate stacking structures 120a and 120b. However, the embodiment is not limited thereto. It is also possible for the gate contact part 184 not to have any curved portion at the boundary of the plurality of gate stacking structures 120a and 120b. Numerous other variations are possible.

Referring to FIG. 2, in an embodiment, the plurality of gate stacking structures 120a and 120b of the gate electrodes 130 and the interlayer insulating layers 132m may be extended in the first direction (DR1 of the drawing) in the connection region 104. The plurality of gate electrodes 130 may be sequentially and/or selectively removed in the connection region 104 to form a step-like configuration, in which the vertical position of the topmost gate electrode at different horizontal locations gradually lowers in a direction away from the cell array region 102. In an embodiment, the length of the plurality of gate electrodes 130 may sequentially increase as the position moves downward. For example, the plurality of gate electrodes 130 may have a step shape arrangement including steps that go downward in a direction away from the cell array region 102. The plurality of gate electrodes 130 may have a step shape arrangement in one direction or a plurality of directions. Accordingly, the plurality of pad portions PP of the plurality of connection gate electrodes 130c may have a form in which they are each exposed upward. For example, though the plurality of gate electrodes 130 are depicted as having a step shape arrangement in one direction (in the first direction DR1) in the figure, the embodiments are not limited there to. For example, the gate stacking structure 120 may descend in a stepped manner in a plurality of directions (e.g., to form a pyramid-like shape). Accordingly, the plurality of topmost gate electrodes at different horizontal locations (pad portions PP of the plurality of connection gate electrodes 130c) may be exposed upward in a stepped manner in a process step

The plurality of gate contact parts 184 may be electrically connected to a corresponding one (or corresponding plurality of) the pad portions PP of the connection gate electrode 130c.

In an embodiment, each gate contact part 184 may be electrically connected to the circuit region 200 through the gate stacking structure 120 in the connection region 104. At this time, the gate contact part 184 may be electrically connected to the connection gate electrode 130c having the pad portion PP among the plurality of gate electrodes 130 included in the gate stacking structure 120, and may be insulated from the remaining gate electrode 130r with an insulating pattern 280 therebetween. The insulating pattern 280 may include a first insulating pattern 281 positioned along the circumference of the space in which the insulating pattern 280 is formed, a second insulating pattern 282 positioned between the first insulating patterns 281, and a third insulating pattern 283 capping the space in which the insulating pattern 280 is formed. The first insulating patterns 281 may have a recess, in which second insulating pattern 282 is formed. The third insulating pattern 283 may fill the space in which the insulating pattern 280 is formed. For example, the third insulating patterns 283 may be disposed between the gate contact part 184 and first insulating patterns 281. The first insulating pattern 281 may include silicon oxide, the second insulating pattern 282 may include SiON (silicon oxynitride), and the third insulating pattern 283 may include SiN (silicon nitride). However, this is one example and the present disclosure is not limited thereto. Additionally, although not shown, an interface insulating pattern may be positioned between the first insulating pattern 281 and the gate electrode 130. The interface insulating pattern may include SiON, but is not limited thereto. The shape and material of the insulating pattern 280 will be described separately later in detail.

The pad portion PP may be positioned at the end of the connection gate electrode 130c far from the cell array region 102 and may have a larger thickness than other parts. The gate contact part 184 may be connected to the inner surface of the pad portion PP while penetrating the pad portion PP of the connection gate electrode 130c. For example, the pad portion PP may be positioned at the connection gate electrode 130c which is the farthest one among the gate electrodes 130 from the cell array region 102 and may have a larger thickness than other gate electrodes. The gate contact part 184 may be in contact with the pad portion PP while penetrating the pad portion PP of the connection gate electrode 130c. For example, the gate contact part 184 may be provided with a connection part 184c that protrudes toward the surface of the pad portion PP and is in contact with the pad portion PP. The gate contact part 184 may extend through the gate stacking structure 120 to a pad portion provided at the top of the plurality of wiring layers 236 of the circuit region 200, and be electrically connected to the pad portion. Accordingly, a design degree of freedom of the second wire part 180 may be improved by being connected to the circuit region 200 without additional connecting wires. However, the configuration to connect the gate contact part 184 and the circuit region 200 may be varied in various ways.

The gate contact part 184 may include a conductive material, for example, tungsten (W), copper (Cu), aluminum (Al), etc., and may further include a diffusion barrier layer. However, the embodiment is not limited to the material of gate contact part 184.

Referring to FIG. 1 and FIG. 2, the dummy structure DH may be provided. The dummy structure DH may penetrate the gate stacking structure 120 in substantially the same way as the gate contact part 184. Referring to FIG. 2, the dummy structure DH may have a protrusion portion 284A protrusion portion and penetrates the gate stacking structure 120 in the third direction DR3, and the extension portion 284A may extend in the second direction DR2 in the region parallel to the gate electrode 130. The protrusion portion 284A may be a part of an extension portion DHC. The extension portion DHC may be filled with an insulating pattern 280 (e.g., 2822 and 2812). For example, the dummy structure DH may include an elongated insulating body and a plurality of protrusion portions 284a, and the elongated insulating body penetrates the gate stacking structure 120 in the third direction DR3 and extends vertically (in the third direction DR3). The plurality of protrusion portions 280a may protrude from the elongated insulating body in the second direction DR2 and extend parallel to the gate electrode 130. The elongated insulating body and a plurality of protrusion portions 280a may be filled with an insulating pattern 280. The insulating pattern 280 may include a first insulating pattern 281 (2812) positioned along the circumference of the space in which the insulating pattern 280 is formed, and a second insulating pattern 282 (2822) positioned between the first insulating patterns 281. Unlike the gate contact part 184, the insulating pattern 280 in contact with the dummy structure DH may not include the third insulating pattern 283. As shown in FIG. 2, the interior of the dummy structure DH may be filled with the fourth insulating pattern 284. The fourth insulating pattern 284 may include silicon oxide. As shown in FIG. 2, the fourth insulating pattern 284 may include a first portion 284a positioned in the extension portion DHC and a second portion 284b positioned in the penetration hole of the dummy structure DH. The first portion 284a and the second portion 284b may be formed by different processes, but may include the same material. Therefore, the boundary between the first portion 284a and the second portion 284b may not be recognized. Alternatively, the first portion 284a and the second portion 284b may be formed in the same process.

Referring to FIG. 1 and FIG. 2, a part of the dummy structures DH may be positioned to overlap the staircase portion of the gate stacking structure 120. For example, as shown in FIG. 1 and FIG. 2, the dummy structure DH may be positioned to overlap the part where the step is formed due to the different thickness of the gate stacking structure 120. For example, the connection region includes first and second connection regions which are divided by a vertical plane intersecting the dummy pattern DH, and a vertical thickness of the first connection region is greater than that of the second connection region such that the gate stack includes a step shape in a cross sectional view.

Since the steps of the gate stacking structure 120 that overlaps the dummy structure DH are different, the shape of the dummy structure DH in a plan view may not be formed uniformly (or may be formed abnormally) when the dummy structure DH is formed. As will be explained in detail later, during the process of forming and expanding the penetration hole for forming the dummy structure DH, the diameter of the penetration hole may be formed differently due to the difference in an etch rate for each region, in the subsequent forming process of the insulating pattern 280. As a result, the insulating pattern 280 (particularly a third insulating pattern 283) may be formed abnormally (or in an unwanted portion). This may cause a short circuit as a part of the insulating pattern 280 is replaced with a metal material during the subsequent formation process of the gate electrode 130.

Accordingly, in the semiconductor device according to the present embodiment, the insulating pattern 280 positioned between the gate contact part 184 and the gate electrode 130 may include a third insulating pattern 283. The insulating pattern 280 positioned between the dummy structure DH and the gate electrode 130 may not include the third insulating pattern 283. Alternatively, the horizontal thickness of the third insulating pattern 283 positioned between the dummy structure DH and the gate electrode 130 may be formed thinner than the horizontal thickness of the third insulating pattern 283 in contact with the gate contact part 184. In this way, the occurrence of a short circuit may be prevented by not including the third insulating pattern 283 in the dummy structure DH or by forming the horizontal thickness of the third insulating pattern 283 thin.

As described above, the third insulating pattern 283 may include SiN. When the SiN is replaced by a conductive material during the formation process of the gate electrode, the replacement operation may cause a short circuit near the dummy structure DH. However, the semiconductor device, according to the present embodiment, may prevent such short circuits by removing or thinning the SiN in the region adjacent to the dummy structure DH. Below, the shape of the insulating pattern 280 around the gate contact part 184 and the dummy structure DH is described in detail with reference to drawings.

FIG. 4 is an enlarged view of a region indicated by C in FIG. 2. FIG. 5 is an enlarged view of a region indicated by D in FIG. 2. FIG. 4 illustrates the gate contact part 184 and the peripheral region thereof, and FIG. 5 illustrates the dummy structure DH and the peripheral region thereof. Referring to FIG. 4, an insulating pattern 280 is positioned between the gate contact part 184 and the gate electrode 130. As described above, the insulating pattern 280 may include a first insulating pattern 2811 positioned along the circumference of the space in which the insulating pattern 280 is formed, a second insulating pattern 2821 positioned between the first insulating pattern 281, and a third insulating pattern 283 capping the space in which the insulating pattern 280 is formed. The first insulating pattern 281 may include silicon oxide, the second insulating pattern 2821 may include SiON, and the third insulating pattern 283 may include SiN. Since the insulating pattern 280 has the multi-layer structure, the interior of the insulating pattern 280 may be sufficiently filled during the formation of the insulating pattern 280. In addition, since the insulating pattern 280 is capped with the third insulating pattern 283, the insulating pattern 280 may be protected from an etching solution of the subsequent process, for example, HF (hydrofluoric acid). In the forming process of the semiconductor device, a sacrificial layer inside the gate contact part 184 may be removed and a conductive material may be filled to electrically connect the gate contact part 184 and the gate electrode 130. At this time, a process of removing the insulating material inside (or at the interface) of the gate contact part 184 may be performed to achieve electrical contact between the gate contact part 184 and the gate electrode 130, and it may be preferable to protect the insulating pattern 280 from being etched by the etching solution used at this time. The third insulating pattern 283 including SiN may protect the insulating pattern 280, particularly the first insulating pattern 281, from the etching solution of this process. Since the insulating material inside or at the interface of the gate contact part 184 may include silicon oxide, and the first insulating pattern 281 may also include silicon oxide, if the first insulating pattern 281 is not capped with the third insulating pattern 283, the first insulating pattern 281 may be etched. However, in the present embodiment, the third insulating pattern 283 may cap (or may protect) the first insulating pattern 281, thereby preventing the etching of the first insulating pattern 281.

Referring to FIG. 5, the insulating pattern 280 is positioned between the dummy structure DH and the gate electrode 130. As described above, the insulating pattern 280 positioned between the dummy structure DH and the gate electrode 130 may include the first insulating pattern 2812 positioned along the circumference of the space in which the insulating pattern 280 is formed and the second insulating pattern 2822 positioned between portions of the first insulating pattern 2812, but may not include the third insulating pattern 283. Since this is not a place where conductive material is filled in the case of the dummy structure DH, a process for removing the insulating material inside or at the interface of the dummy structure DH may not be performed. Therefore, a process using the etching solution such as HF may not be performed, and the third insulating pattern 283 to protect the insulating pattern 280 from the etching solution may not be provided. Rather, the third insulating pattern 283 including SiN may cause an unnecessary short circuit when it is replaced by a conductive material during the formation of the gate electrode during the process. Particularly, as described above, the dummy structure DH is formed at a part where the thickness of the gate stacking structure changes, e.g., a step part is formed, and thus the shape of the dummy structure DH in a plan view may not be formed evenly in a circular shape, and thus the third insulating pattern 283 may be formed non-uniformly. If the third insulating pattern 283 is formed non-uniformly, the possibility of causing the short circuit may increase.

Accordingly, in the semiconductor device according to the present embodiment, the third insulating pattern 283 may be removed from the insulating pattern 280 around the dummy structure DH. This may prevent the short circuit caused by the conductive material substitution of the third insulating pattern 283 including SiN.

Referring to FIG. 5, the insulating pattern 280 around the dummy structure DH may include a fourth insulating pattern 284 instead of the third insulating pattern 283. As shown in FIG. 5, the fourth insulating pattern 284 may include a first portion 284a and a second portion 284b. The first portion 284a and the second portion 284b may include the same material. For example, the first portion 284a and the second portion 284b may include silicon oxide. If the first portion 284a and the second portion 284b include the same material, the boundary between the first portion 284a and the second portion 284b may not be recognized. The first portion 284a may be positioned in the region where the third insulating pattern 283 was positioned in FIG. 4. For example, the first portion 284a may correspond to the third insulating pattern 283 in FIG. 4, in terms of the positional relationship among components. As explained separately later, the first portion 284a of the fourth insulating pattern 284 of the dummy structure DH may be formed in the region where the third insulating pattern 283 was positioned during the manufacturing process. For example, the shape of the first portion 284a of the fourth insulating pattern 284 of the dummy structure DH may have substantially the same shape as the third insulating pattern 283 of the gate contact part 184.

Referring to FIG. 4 and FIG. 5 simultaneously, the planar diameter D2 of the dummy structure DH may be larger than the planar diameter D1 of the gate contact part 184. The forming process of the penetration holes for forming the gate contact part 184 and the dummy structure DH are performed in the same process, but in an expansion process after forming the penetration hole, the penetration hole of the dummy structure DH may expand more than the penetration hole of the gate contact part 184. Therefore, the planar diameter D2 of the dummy structure DH may be larger than the planar diameter D1 of the gate contact part 184. In some embodiments, the diameter may be a diameter of the widest part. In some embodiments, the planar diameter D2 of the dummy structure DH may be larger than the planar diameter D1 of the gate contact part 184 by 10% to 15%.

In the previous embodiment, the embodiment was described in which the dummy structure DH does not include the third insulating pattern 283, but in another embodiment, the dummy structure DH may include the third insulating pattern 283. In this case, the horizontal thickness of the third insulating pattern 283 in the first direction DR1 in contact with the dummy structure DH may be thinner than the horizontal thickness of the third insulating pattern 283 in the first direction DR1 in contact with the gate contact part 184.

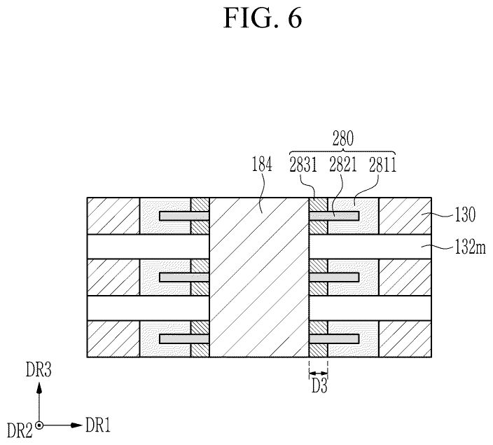

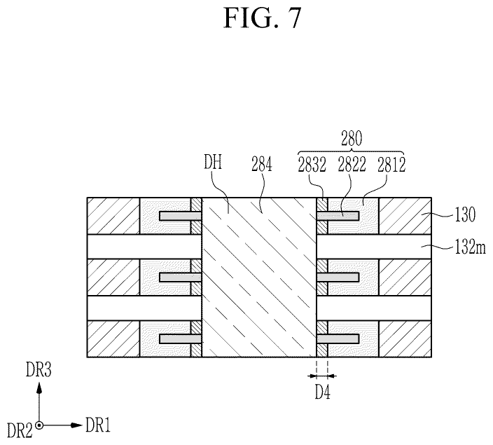

FIG. 6 and FIG. 7 illustrate the same region as FIG. 4 and FIG. 5, respectively, for another embodiment. For example, FIG. 6 illustrates the same region as FIG. 4, for example, the gate contact part 184 and the surrounding insulating pattern 280, and FIG. 7 illustrates the same region as FIG. 5, the dummy structure DH, and the surrounding insulating pattern 280. Referring simultaneously to FIG. 6 and FIG. 7, both the insulating pattern 280 adjacent to the gate contact part 184 and the insulating pattern 280 adjacent to the dummy structure DH may include a first insulating pattern 281 (2811 and 2812) positioned along the circumference of the space in which the insulating pattern 280 is formed, a second insulating pattern 282 (2821 and 2822) positioned between the first insulating pattern 281, and a third insulating pattern 283 (2831 and 2832) capping the space in which the insulating pattern 280 is formed. However, when comparing FIG. 6 and FIG. 7, the horizontal thickness D3 of the third insulating pattern 2831 in contact with the gate contact part 184 in the first direction DR1 may be thicker than the horizontal thickness D4 of the third insulating pattern 2832 in contact with the dummy structure DH in the first direction DR1. This is because, in the process of removing the third insulating pattern 2832 adjacent to the dummy structure DH, only a portion thereof may be removed to reduce the horizontal thickness of the third insulating pattern 2832, which will be explained separately later. For example, in the semiconductor device according to an embodiment, the horizontal thickness D3 of the third insulating pattern 2831 in contact with the gate contact part 184 may be thicker than the horizontal thickness D4 of the third insulating pattern 2832 in contact with the dummy structure DH. In the embodiment of FIG. 7, the fourth insulating pattern 284 may be positioned inside the penetration hole of the dummy structure DH. The fourth insulating pattern 284 may include silicon oxide. In the embodiment of FIG. 6, a conductive material, for example, tungsten (W), copper (Cu) or aluminum (Al), may be positioned inside the penetration hole of the gate contact part 184. For example, the gate contact part 184 may be formed of a conductive material, for example, tungsten (W), copper (Cu) or aluminum (Al).

In an embodiment, the horizontal thickness D3 of the third insulating pattern 2831 positioned adjacent to the gate contact part 184 in the first direction DR1 may be 1 nm to 20 nm. However, this is just one example and the present invention is not limited to this. As described above, in an embodiment, the horizontal thickness of the third insulating pattern 1431 positioned adjacent to the gate contact part 184 may be thicker than the horizontal thickness of the third insulating pattern 1432 positioned adjacent to the dummy structure DH.

In this way, the semiconductor device according to the present embodiment may prevent the short circuit of the dummy structure DH by removing the third insulating pattern 2832 including SiN in the insulating pattern 280 adjacent to the dummy structure DH or reducing the horizontal thickness thereof.

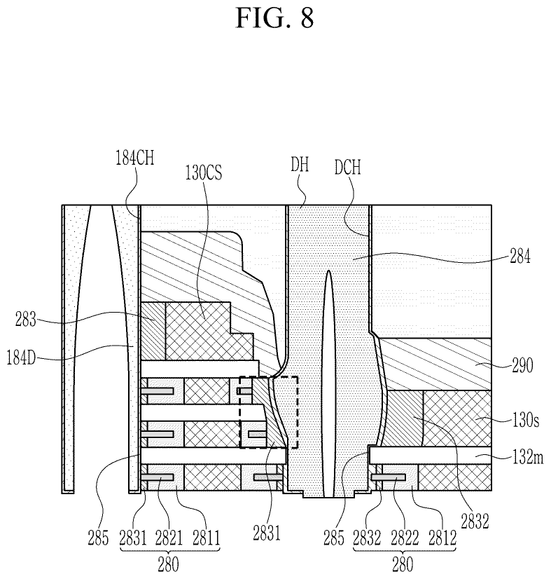

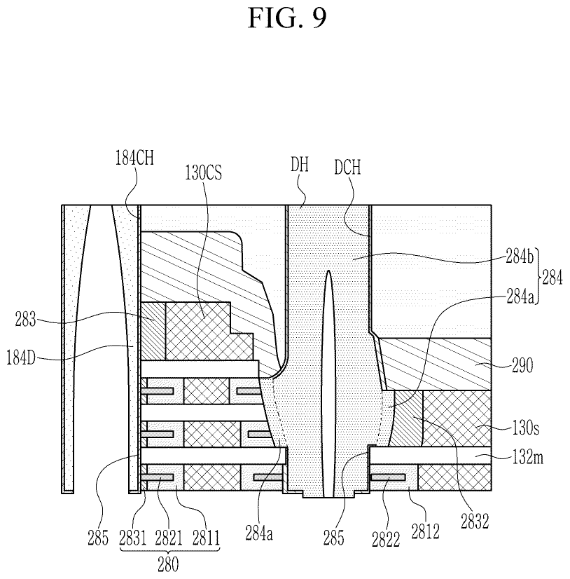

FIG. 8 is a simplified illustration of a cross-section of the gate contact part 184 and the dummy structure DH in an embodiment in which the dummy structure DH and the gate contact part 184 include the third insulating pattern 283 of substantially the same horizontal thickness. FIG. 9 is a simplified illustration of the cross-section of the gate contact part 184 and the dummy structure DH in an embodiment where the dummy structure DH does not include the third insulating pattern 283.

FIG. 8 and FIG. 9 illustrate the cross-sections of intermediate structures during the manufacturing process for better comprehension and ease of description. For example, they do not show the final completed semiconductor device, but rather a cross-section of the device at intermediate stages during the process of forming the semiconductor device. Referring to FIG. 8 and FIG. 9, sacrificial insulation layers 130s and interlayer insulating layers 132m are alternately stacked. The penetration hole DCH of the dummy structure DH and the penetration hole 184CH of the gate contact part 184 are positioned through each stack. The penetration hole of the gate contact part 184 may be filled with the gate contact part dummy material 184D. The gate contact part dummy material 184D may include carbon-based materials, but is not limited thereto. As shown in FIG. 8, the thickness of the topmost sacrificial insulation layer 130CS, which is positioned at the uppermost position among the sacrificial insulation layers 130s, may be thicker than the thicknesses of the other sacrificial insulation layers 130s. The topmost sacrificial insulation layer 130CS with the thickest thickness may be replaced by the connection gate electrode 130c in a subsequent process step, as can be more clearly understood from the manufacturing method described later. The connection gate electrode 130c may be electrically connected to the gate contact part 184.

An insulating pattern 280 may be positioned between the gate contact part 184 and the sacrificial insulation layer 130s. The description of the insulating pattern 280 in contact with the gate contact part 184 may be omitted as it is substantially the same as previously explained. A fifth insulating pattern 285 may be positioned between the sidewall of the penetration holes of the gate contact part 184 and the insulating pattern 280. The fifth insulating pattern 285 may include silicon oxide. The fifth insulating pattern 285 is an insulation layer and is removed in order to electrically connect the gate contact part 184 and the connection gate electrode 130c in the subsequent step.

As shown in FIG. 8, the dummy structure DH may be formed in the step portion of the gate stacking structure. As shown in FIG. 8, an upper insulating pattern 290 may be positioned on the gate stacking structure. The upper insulating pattern 290 may include silicon oxide, but is not limited thereto. The upper insulating pattern 290 may cover the upper surface of the gate stacking structure. The upper insulating pattern 290 may be formed by an atomic layer deposition (ALD) process.

As will be explained separately later, after the penetration hole is formed for the formation of the dummy structure DH and the gate contact part 184, an expansion process of the penetration hole may be performed. At this time, the dummy structure DH is formed at the step of the gate stacking structure and may be in contact with the upper insulating pattern 290 on the plane, at this time, the etch selectivity may be different at the portion in contact with the upper insulating pattern 290 and the portion in contact with the gate stacking structure. Therefore, an over-etching may occur in some regions. This may cause a problem in that the third insulating pattern 283 is connected between the neighboring insulating patterns 280 and formed into one during the subsequent formation process of the insulating pattern 280. This is illustrated in the region indicated by the dotted line in FIG. 8. As shown in FIG. 8, when the third insulating pattern 283 is connected in some region of the dummy structure DH, the third insulating pattern 283 may be replaced with a metal in the process of replacing the sacrificial insulation layer 130s with the gate electrode 130. At this time, the third insulating pattern 283, which preferably be insulated from each other, may be connected as one, causing a short circuit. For example, an etching process may be performed at the step of the gate stacking structure to form the penetration hole, and the upper insulating pattern 290 and the insulating pattern 280 may be partially removed. During the etching, the sidewall of the penetration hole may have irregularity due to the etch selectivity difference of the material to be removed. As a result, the third insulating pattern 283 (2831) may be connected to and disposed between the neighboring insulating patterns 280 during the subsequent formation process of the insulating pattern 280. In a subsequent step of replacing the sacrificial insulation layer 130s with the gate electrode 130, the third insulating pattern 283 may be replaced with, e.g., a metal, thereby causing a short circuit.

Accordingly, the semiconductor device according to the present embodiment may prevent this short circuit by removing the third insulating pattern 283 around the dummy structure DH. FIG. 9 is a simplified illustration of the cross-section of the gate contact part 184 and the dummy structure DH in the present embodiment, where the dummy structure DH does not include the third insulating pattern 283. The detailed description of the same components as shown in FIG. 8 may be omitted.

Referring to FIG. 9, the third insulating pattern 283 is removed from the region adjacent to the dummy structure DH. Particularly, the third insulating pattern 283, which was connected as one in FIG. 8, may be removed and the first portion 284a of the fourth insulating pattern 284 may be positioned in the place thereof. Additionally, the second portion 284b of the fourth insulating pattern 284 may be positioned inside the dummy structure DH. When the first portion 284a and the second portion 284b of the fourth insulating pattern 284 include the same material, the boundary between the first portion 284a and the second portion 284b may not be recognized. As shown in FIG. 9, the third insulating pattern 283, which is connected to each other, is removed, and a short circuit caused by the subsequent replacement of the conductive material of the third insulating pattern 283 may be prevented. For example, the third insulating pattern 283 may not be disposed between the dummy structure DH and the interlayer insulating layer 132m. As a result, a short circuit may not occur.

After the structure shown in FIG. 9 is subject to the subsequent replacement of the conductive material of the third insulating pattern 283, the dummy pattern DH may be in contact with both the gate stacking structure (which corresponds to the region of the sacrificial insulation layers 130s and the interlayer insulating layer 132m) and the upper insulating pattern 290.

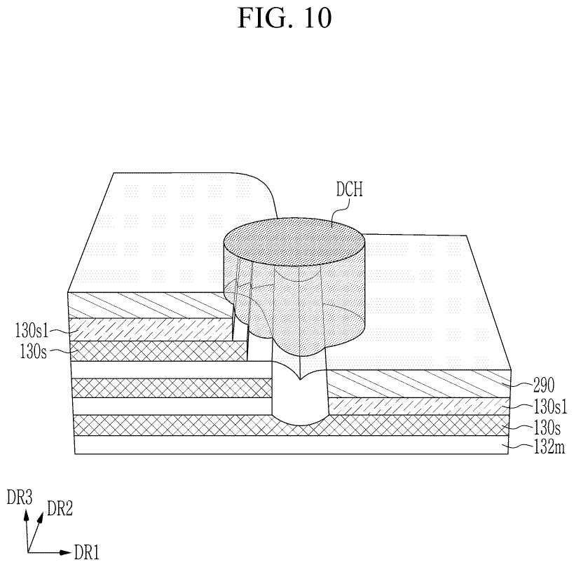

FIG. 10 is a three-dimensional diagram of a formation region of the dummy structure DH and illustrates an intermediate structure during the manufacturing process. Referring to FIG. 10, alternately stacked sacrificial insulation layers 130s and interlayer insulating layers 132m are positioned. At this time, an additional sacrificial insulation layer 130s1 may be positioned on top of the sacrificial insulation layer 130s positioned at the topmost level. This may facilitate the contact between the gate contact part 184 and the gate electrode 130 while ensuring that the gate electrode 130 has the thicker thickness than other regions when the sacrificial insulation layer 130s and additional sacrificial insulation layer 130s1 are later replaced with the gate electrode 130. For example, the additional sacrificial insulation layer 130s1 may be used to form the contact between the gate contact part 184 and the gate electrode 130 while ensuring that the topmost one of the gate electrodes 130 has the thicker thickness than other gate electrodes 130. Additionally, an upper insulating pattern 290 may be positioned at the top of the gate stacking structure.

As described above, after forming the penetration holes DCH (which is illustrated as a filled area in the drawings for convenience) for forming the gate contact part 184, an expansion process of the penetration hole may be performed. At this time, as shown in FIG. 10, the penetration holes for the dummy structure DH may be positioned in the step portion of the gate stacking structure, so the expansion of the penetration hole DCH of the dummy structure DH may not be uniform.

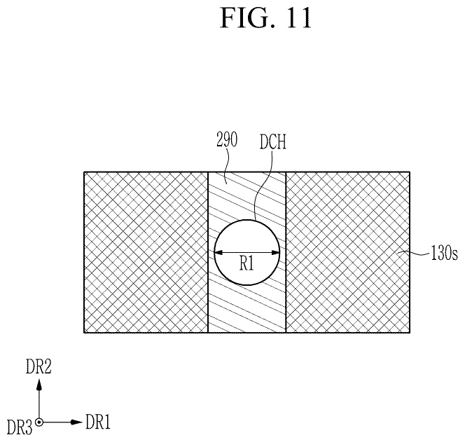

FIG. 11 to FIG. 16 are views illustrating a forming process of a dummy structure DH (e.g., intermediate structures during a series of process steps in the manufacturing process) according to an embodiment. FIG. 11 to FIG. 16 illustrate the horizontal cross-sections in a direction parallel to the substrate of FIG. 10 (or parallel to the surfaces of the sacrificial insulation layer 130s). Referring to FIG. 11, an upper insulating pattern 290 may be positioned between the sacrificial insulation layers 130s in a plan view. For example, for the penetration hole of the dummy structure DH, the sacrificial insulation layer 130s may be positioned in the first direction DR1, and the upper insulating pattern 290 may be positioned in the second direction DR2. In FIG. 11, the planar diameter R1 of the penetration hole of the dummy structure DH is shown.

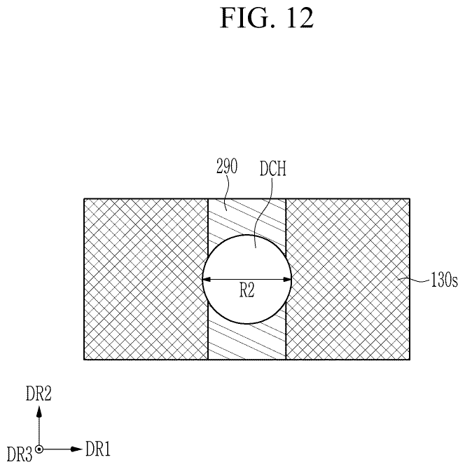

Next, referring to FIG. 12, the penetration hole DCH of the dummy structure DH may be expanded. At this step, the planar diameter R2 of the penetration hole of the dummy structure DH may be expanded (or enlarged). At this stage, the planar diameter of the entire penetration hole may be expanded. For example, in this step, both the laminated sacrificial insulation layer 130s and the interlayer insulating layer 130m may be partially etched.

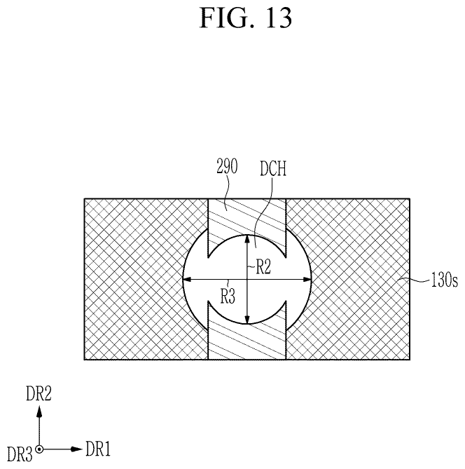

Next, referring to FIG. 13, a space in which an insulating pattern 280 is formed (in a subsequent process step) may be formed by etching the sacrificial insulation layers 130s positioned on both sides of the penetration hole DCH for the dummy structure DH. Unlike the previous step, in this step, the planar diameter of the entire penetration portion does not increase, but the sacrificial insulation layer 130s in contact with the penetration portion (e.g., an exposed portion of the sacrificial insulation layer 130s to the penetration hole DCH) may be etched, and the interlayer insulating layer 130m may not be etched. Through this step, a space may be secured between the sacrificial insulation layer 130s and the dummy structure DH for forming the insulating pattern 280.

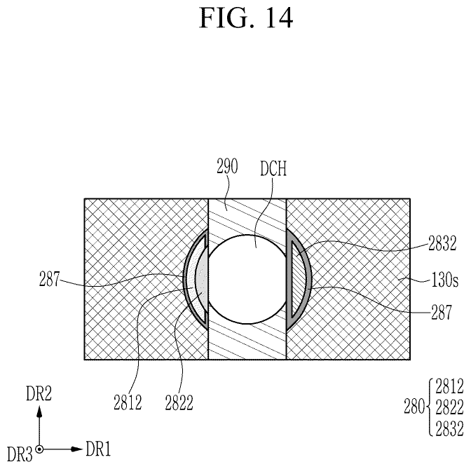

Next, referring to FIG. 14, the insulating pattern 280 may be formed in the etched portion of the sacrificial insulation layer 130s. As described above, the insulating pattern 280 may include the first insulating pattern 281 (2812), the second insulating pattern 282 (2822), and the third insulating pattern 283 (2832). At this time, an interface pattern 287 may be positioned between the insulating pattern 280 and the sacrificial insulation layer 130s. Referring to FIG. 14, the sacrificial insulation layer 130s positioned on one side of the penetration hole DCH for the dummy structure DH may be filled with the interface pattern 287, the first insulating pattern 2812, the second insulating pattern 2822, and the third insulating pattern 2832, and the sacrificial insulation layer 130s positioned on the other side may be filled with the interface pattern 287 and the third insulating pattern 283.

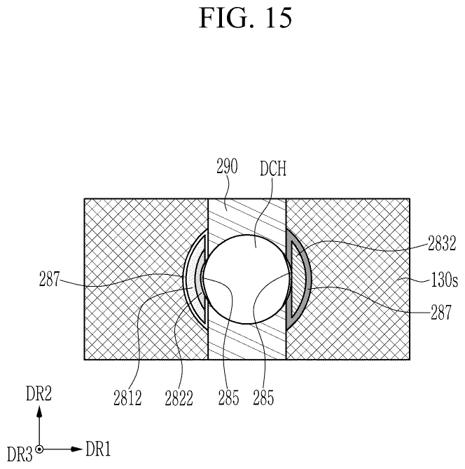

Next, referring to FIG. 15, a fifth insulating pattern 285 may be formed along the circumference of the penetration hole of the dummy structure DH.

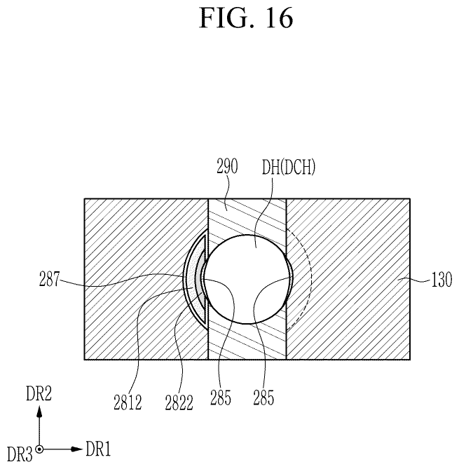

Next, referring to FIG. 16, the sacrificial insulation layer 130s may be removed and replaced with a conductive material to form the gate electrode 130. In this process, the third insulating pattern 283 positioned on one side of the dummy structure DH (or the penetration hole DCH) may be replaced with a conductive material. Even if the third insulating pattern 283 is replaced with a conductive material, a short circuit may not occur because the fifth insulating pattern 285 is positioned around the dummy structure DH.

FIG. 11 to FIG. 16 illustrate the case where the forming process of the dummy structure DH is formed according to an embodiment, and the invention is not limited to the shape illustrated in FIG. 11 to FIG. 16. For example, the shape may be different, e.g., due to the difference in etch selectivity between the sacrificial insulation layer 130s and the upper insulating pattern 290.

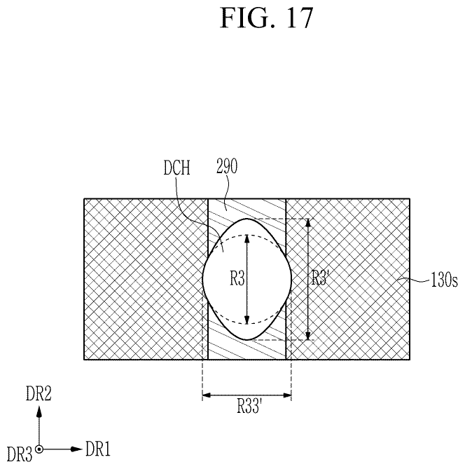

FIG. 17 to FIG. 21 are views illustrating the forming process of the dummy structure DH (e.g., intermediate structures during a series of process steps in the manufacturing process) according to an embodiment. FIG. 17 to FIG. 21 illustrate the horizontal cross-sections in a direction parallel to the substrate or the sacrificial insulation layer 130s. After forming the penetration hole DCH of the dummy structure DH as shown in FIG. 11, the expansion process of the penetration hole DCH may be performed as shown in FIG. 17. At this time, the sacrificial insulation layer 130s may be positioned in the first direction DR1 of the penetration section, and the upper insulating pattern 290 may be positioned in the second direction DR2. At this time, if the material and the etching ratio of the sacrificial insulation layer 130s and the upper insulating pattern 290 are different, the penetration hole DCH may be further extended in the direction of the upper insulating pattern 290. Therefore, the planar diameter R3′ in the second direction DR2 may become longer than the planar diameter R3 that was originally supposed to be expanded. For example, the planar diameter R3′ in the second direction DR2 may become greater than the planar diameter R33′ in the first direction DR1.

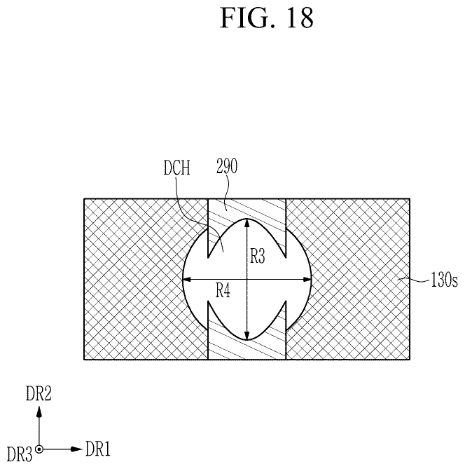

Next, referring to FIG. 18, a space in which an insulating pattern 280 will be formed may be formed by etching the sacrificial insulation layer 130s on both sides of the penetration hole DCH for the dummy structure DH. Unlike the previous step, in this step, the planar diameter of the entire penetration hole does not increase, but the sacrificial insulation layer 130s in contact with the penetration hole (e.g., an exposed portion of the sacrificial insulation layer 130s to the penetration hole DCH) may be etched, and the interlayer insulating layer 130m may not be etched. Through this step, a space for forming the insulating pattern 280 may be secured between the sacrificial insulation layer 130s and the dummy structure DH.

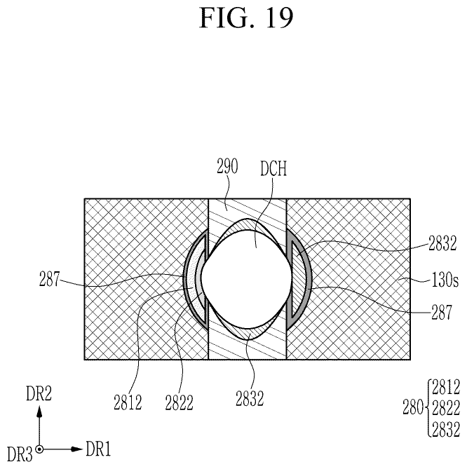

Next, referring to FIG. 19, the insulating pattern 280 is formed in the etched portion of the sacrificial insulation layer 130s. As described above, the insulating pattern 280 may include the first insulating pattern 281 (2812), the second insulating pattern 282 (2822), and the third insulating pattern 283 (2832). At this time, the interface pattern 287 may be positioned between the insulating pattern 280 and the sacrificial insulation layer 130s. Referring to FIG. 19, the sacrificial insulation layer 130s positioned on one side of the penetration hole DCH for the dummy structure DH may be filled with the interface pattern 287, the first insulating pattern 2812, the second insulating pattern 2822, and the third insulating pattern 2832, and the sacrificial insulation layer 130s positioned on the other side may be filled with the interface pattern 287 and the third insulating pattern 283. At this time, the third insulating pattern 2832 may also be formed in the second direction DR2 in the penetration hole of the dummy structure DH in this step. This is because, as explained above, in the expansion process of the penetration hole of FIG. 17, the etching is better performed in the second direction DR2 than in the first direction DR1 (e.g., the etching amount in the second direction DR2 may be greater than in the first direction DR1). At this time, the third insulating pattern 2832 may be formed in the space where the penetration hole of the dummy structure DH is extended in the second direction DR2. Compared to FIG. 14, in the case of FIG. 14, the third insulating pattern 283 is not formed in the space of the penetration hole in the second direction DR2, but in the case of FIG. 19, the third insulating pattern 283 may be formed in the space of the penetration part in the second direction DR2.

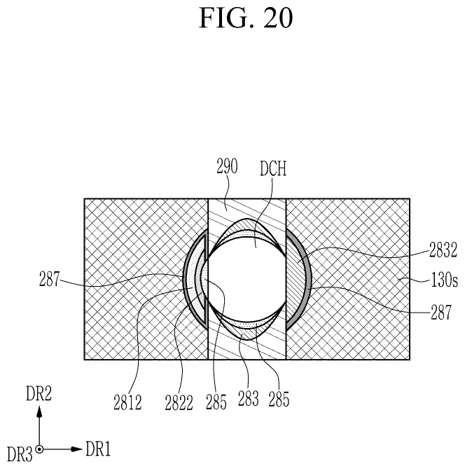

Next, referring to FIG. 20, the fifth insulating pattern 285 is formed along the circumference of the penetration hole of the dummy structure DH.

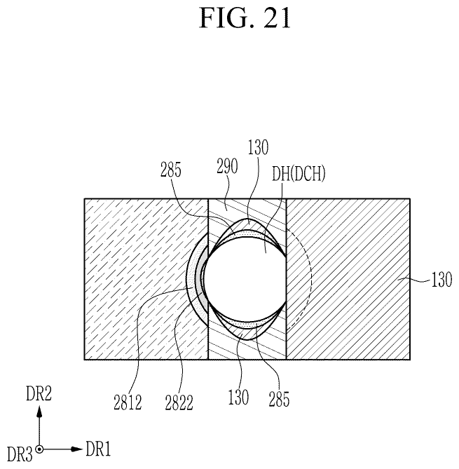

Next, referring to FIG. 21, the sacrificial insulation layer 130s may be removed and replaced with a conductive material to form the gate electrode 130. In this process, the third insulating pattern 283 positioned on one side of the dummy structure DH may be replaced with a conductive material. Also, in this process, the third insulating pattern 283 positioned at the penetration hole of the dummy structure DH may be replaced with a conductive material. As shown in FIG. 21, a short circuit may occur when the third insulating pattern 283 is replaced with a conductive material. For example, as shown in FIG. 21, the conductive material inside the penetration hole of the dummy structure DH and the conductive material inside the space where the insulating pattern is formed may be connected as one. Therefore, a short circuit may occur.

However, the semiconductor device according to an embodiment may prevent this short circuit by removing the third insulating pattern 283 around the penetration hole for the dummy structure DH. As explained above, a short circuit caused by the replacement of the conductive material of the third insulating pattern 283 may be prevented through a process of removing the third insulating pattern 283 around the dummy structure DH in the manufacturing process.

Then, a manufacturing method of the semiconductor device according to an embodiment is described below with reference to drawings. However, the method described below is only an example, and the present invention is not limited thereto. The descriptions with reference to FIGS. 1 to 21 may also be applicable to the following descriptions, unless otherwise indicated by the context. It will be readily understood by those skilled in the art that various modifications and extensions of the present invention may be possible, without departing from the scope of the invention, based on both the foregoing and the following descriptions and embodiments. Furthermore, understanding either the preceding or the following descriptions may be facilitated by referring to the other, as would be readily appreciated by those skilled in the art.

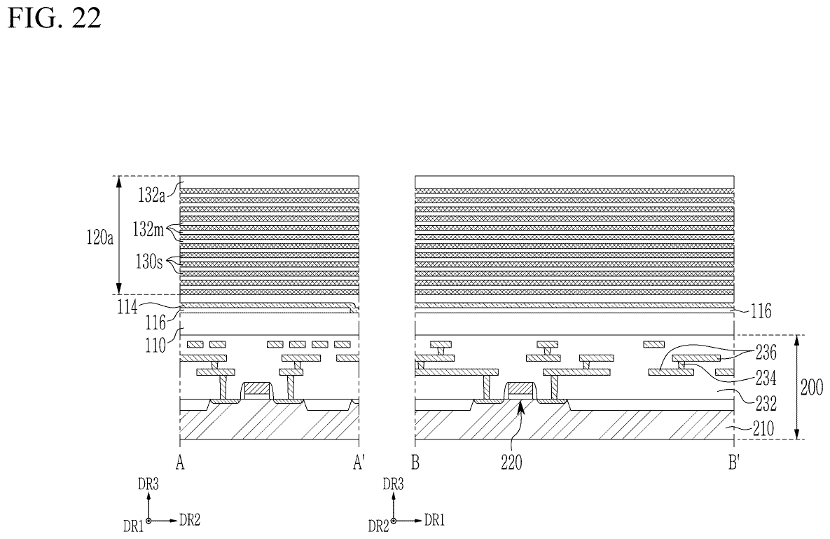

FIG. 22 to FIG. 41 are views illustrating a manufacturing process of a semiconductor device according to an embodiment. Referring to FIG. 22, a plurality of sacrificial insulation layers 130s and a plurality of interlayer insulating layers 132m may be alternately stacked on a circuit region 200 including a peripheral circuit structure to form a first stacking structure 120a, which may be a lower structure chain. A second substrate 110, a horizontal insulation layer 116, a second horizontal conductive layer 114, etc. may be additionally formed between the circuit region 200 and the first stacking structure 120a.

Here, the first stacking structure 120a may include alternately stacked sacrificial insulation layers 130s and interlayer insulating layers 132m, and a first upper insulation layer 132a covering them entirely.

For example, the horizontal insulation layer 116 and the second horizontal conductive layer 114 may be formed on the second substrate 110, and the interlayer insulating layer 132m and the sacrificial insulation layer 130s may be alternately stacked thereon, so that the first upper insulation layer 132a may be formed. Here, the sacrificial insulation layer 130s may be a layer that is replaced with the gate electrode (a reference numeral 130 of FIG. 2, the same hereinafter) through a subsequent process, and at least a portion of the horizontal insulation layer 116 may be a layer that is replaced by the first horizontal conductive layer (which corresponds to reference numeral 112 of FIG. 2; the same applies hereinafter) through a subsequent process. For example, the sacrificial insulation layer 130s may be formed to correspond to a portion where the gate electrode 130 is to be formed, and the horizontal insulation layer 116 may be formed to include a portion where the first horizontal conductive layer 112 is to be formed.

The horizontal insulation layer 116 and/or the sacrificial insulation layer 130s may be formed of a material different from the interlayer insulating layer 132m. For example, the interlayer insulating layer 132m may include silicon oxide, silicon nitride, silicon oxynitride, a low dielectric constant material, etc., the sacrificial insulation layer 130s may include one of silicon, silicon oxide, silicon carbide, silicon nitride, etc., and may be made of a material different from the interlayer insulating layer 132m.

Next, a first upper insulation layer 132a may be formed to entirely cover the sacrificial insulation layer 130s and the interlayer insulating layer 132m.

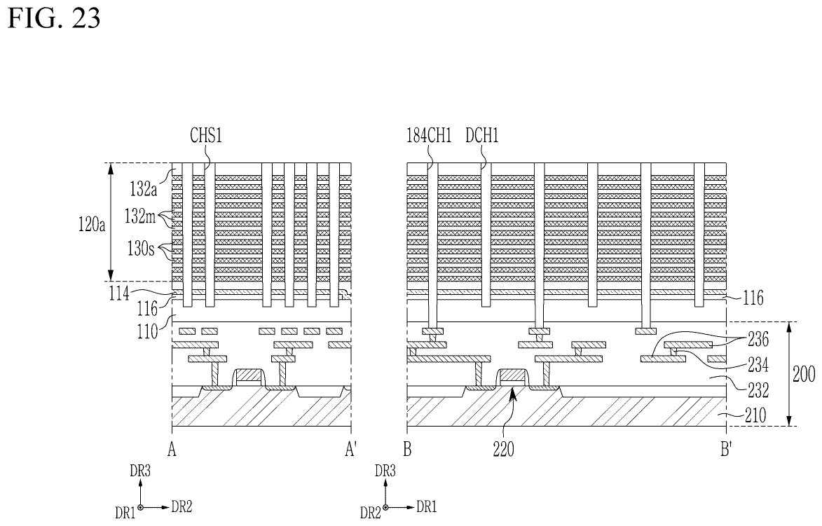

Next, referring to FIG. 23, a first channel penetration hole CHS1 penetrating the first stacking structure 120a in the cell array region 102 may be formed, and a first gate penetration hole 184CH1 and a first dummy penetration hole DCH1 penetrating the first stacking structure 120a in the connection region 104 may be formed.

At this time, the first channel penetration hole CHS1 and the first dummy penetration hole DCH1 may be formed so that one end is positioned on the second substrate 110, and the first gate penetration hole 184CH1 may be formed so that one end penetrates the second substrate 110 and is positioned within the circuit region 200.

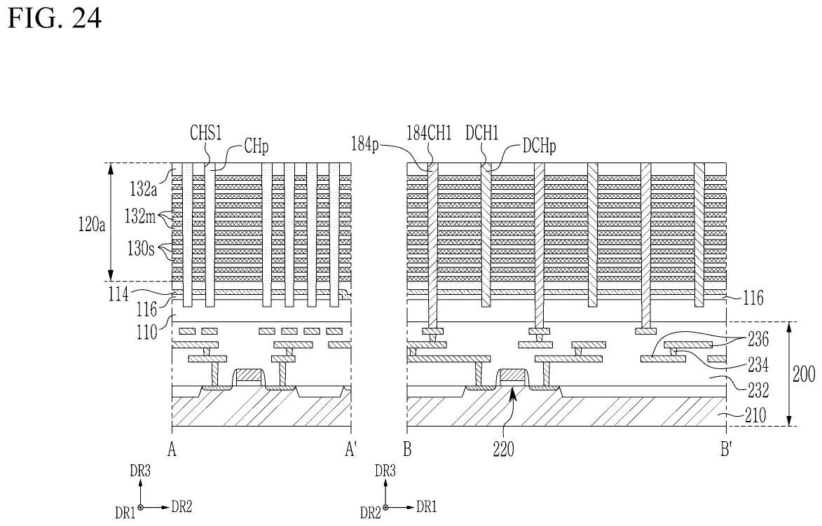

Next, referring to FIG. 24, a sacrificial material may be filled into the first channel penetration hole CHS1, the first gate penetration hole 184CH1, and the first dummy penetration hole DCH1. For example, a channel sacrificial pattern CHp may be formed inside the first channel penetration hole CHS1, a gate sacrificial pattern 184p may be formed inside the first gate penetration hole 184CH1, and a dummy sacrificial pattern DCHp may be formed inside the first dummy penetration hole DCH1. The channel sacrificial pattern CHp may include, for example, polysilicon, and the gate sacrificial pattern 184p and the dummy sacrificial pattern DCHp may include, for example, a carbon-based material. However, the materials included in the channel sacrificial pattern CHp, the gate sacrificial pattern 184p, and the dummy sacrificial pattern DCHp are not limited thereto and may be variously changed.

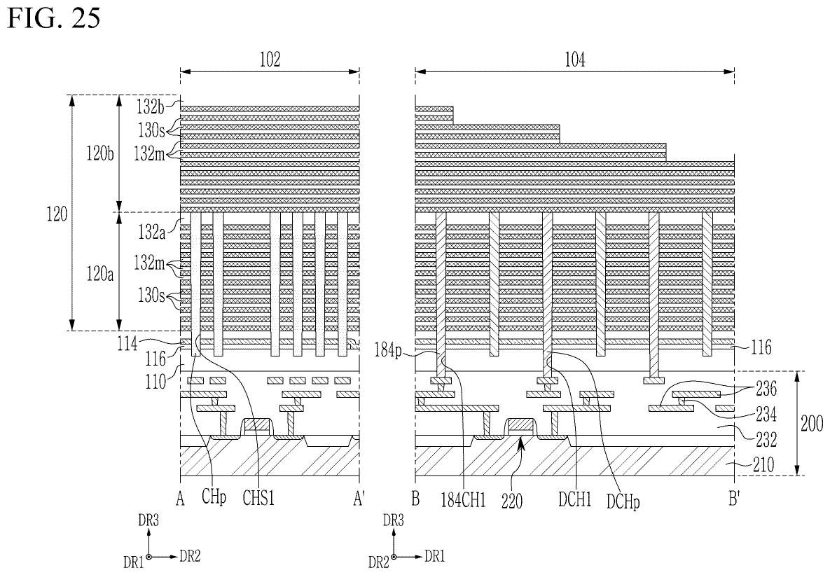

Next, referring to FIG. 25, a second stacking structure 120b may be formed. For example, a plurality of interlayer insulating layers 132m and a plurality of sacrificial insulation layers 130s are alternately stacked to form a second stacking structure 120b. The method for manufacturing the sacrificial insulation layer 130s and the interlayer insulating layer 132m of the second stacking structure 120b may be substantially the same as that of the first stacking structure 120a, and a repeated description thereof may be omitted. By the etching process after the stacking, the second stacking structure 120b may have a step shape in a cross-section in the connection region 104.

Subsequently, additional structures may be formed on the second stack. However, a detailed description of such a process may be omitted, as it will be understood by those skilled in the art, particularly from the description with reference to FIGS. 1 to 25. Therefore, for clarity, such structures are not depicted in FIGS. 25 to 41.

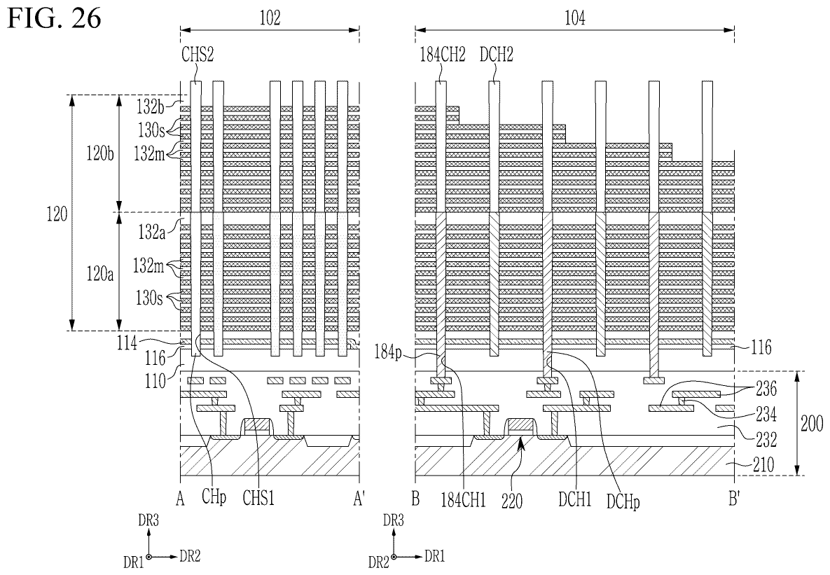

Next, referring to FIG. 26, a second channel penetration hole CHS2 penetrating the second stacking structure 120b in the cell array region 102 may be formed, and a second gate penetration hole 184CH2 and a second dummy penetration hole DCH2 penetrating the first stacking structure 120a in the connection region 104 may be formed.

The second channel penetration hole CHS2 may be formed to overlap the first channel penetration hole CHS1, the second gate penetration hole 184CH2 may be formed to overlap the first gate penetration hole 184CH1, and the second dummy penetration hole DCH2 may be formed to overlap the first dummy penetration hole DCH1.

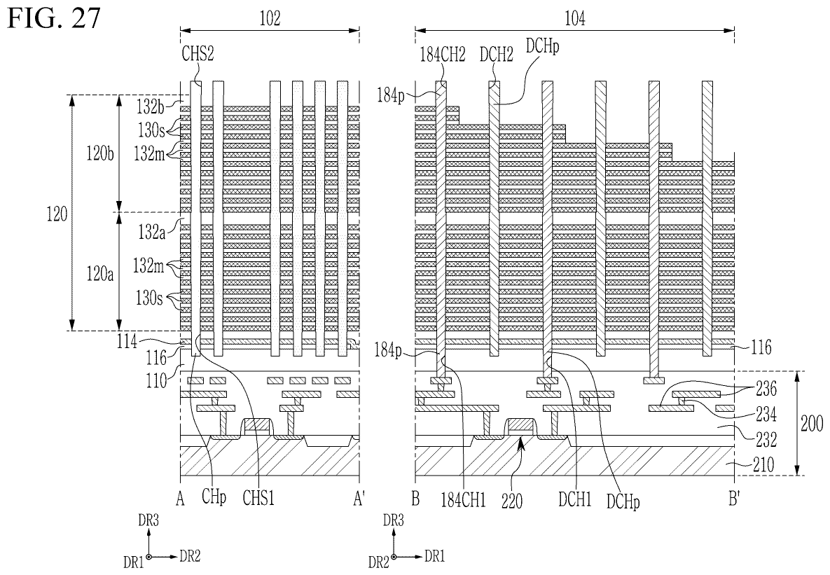

Next, referring to FIG. 27, the second channel penetration hole CHS2, the second gate penetration hole 184CH2, and the second dummy penetration hole DCH2 may be filled with a sacrificial material. For example, a channel sacrificial pattern CHp may be formed inside the second channel penetration hole CHS2, a gate sacrificial pattern 184p may be formed inside the second gate penetration hole 184CH2, and a dummy sacrificial pattern DCHp may be formed inside the second dummy penetration hole DCH2. The channel sacrificial pattern CHp may include, for example, polysilicon, and the gate sacrificial pattern 184p and the dummy sacrificial pattern DCHp may include, for example, a carbon-based material. However, the materials included in the channel sacrificial pattern CHp, the gate sacrificial pattern 184p, and the dummy sacrificial pattern DCHp are not limited thereto and may be variously changed.

Next, referring to FIG. 28, the channel sacrificial pattern CHp positioned within the first channel penetration hole CHS1 and the second channel penetration hole CHS2 in the region corresponding to the cell array region 102 is removed.

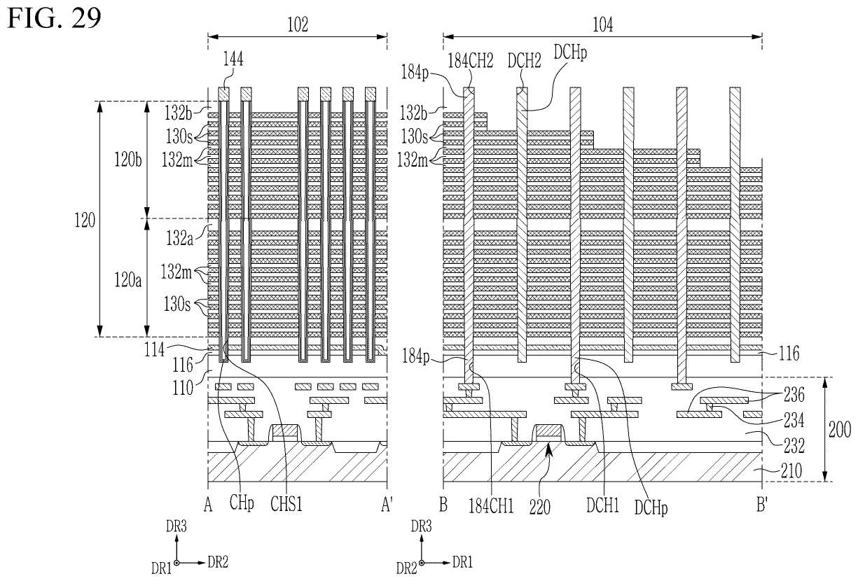

Next, referring to FIG. 29, a channel structure CH is formed in the hole from which the channel sacrificial pattern CHp has been removed. For example, a gate dielectric layer (referring to ‘146’ in FIG. 2), a channel layer (referring to ‘140’ in FIG. 2), a core insulation layer (referring to ‘142’ in FIG. 2) may be sequentially formed to fill the hole formed by removing the sacrificial pattern, and a channel pad (referring to ‘144’ in FIG. 2) may be formed.

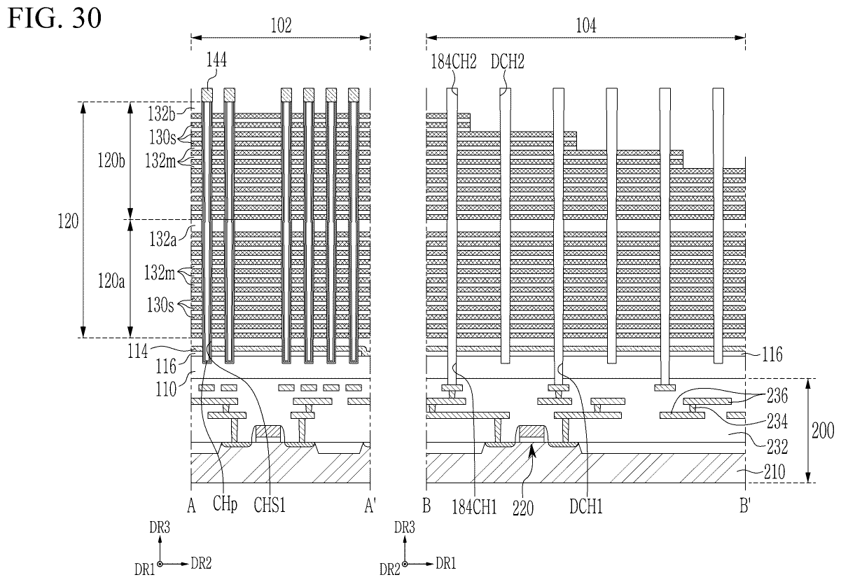

Next, referring to FIG. 30, the gate sacrificial pattern 184p positioned inside the first gate penetration hole 184CH1 and the second gate penetration hole 184CH2, and the dummy sacrificial pattern DCHp positioned inside the first dummy penetration hole DCH1 and the second dummy penetration hole DCH2 are removed.

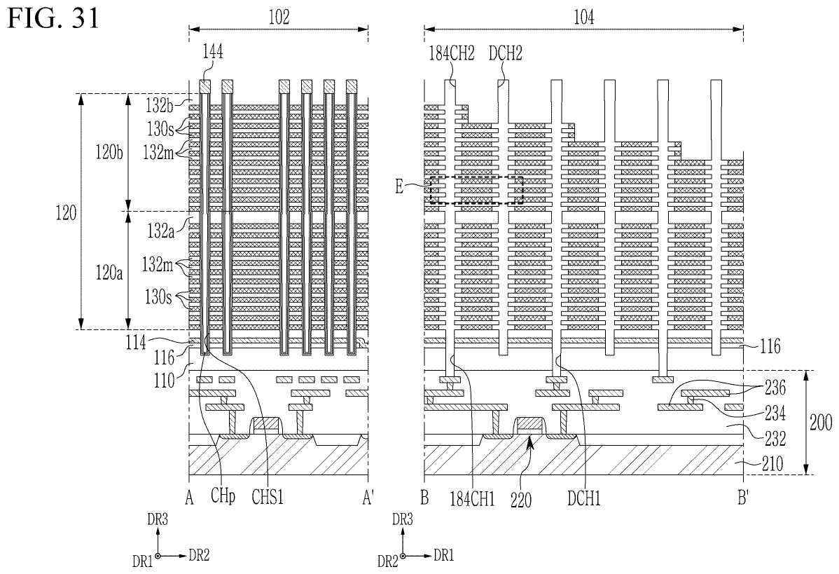

Next, referring to FIG. 31, the expansion process of the first gate penetration hole 184CH1 and the second gate penetration hole 184CH2, the first dummy penetration hole DCH1 and the second dummy penetration hole DCH2 is performed. In the previous step, the formation of the channel penetration hole, the gate penetration hole, and the dummy penetration hole is performed by the same process, and the channel penetration hole, the gate penetration hole, and the dummy penetration hole may have the similar diameters. However, for the effective operation of the semiconductor device, the planar diameter of the gate penetration hole and the dummy penetration hole may preferably be larger than the channel penetration hole, therefore, in this step, the planar diameter of the gate penetration hole and the dummy penetration hole may be increased through the expansion process of the gate penetration hole and the dummy penetration hole. At this time, the expansion process of the gate penetration hole and the dummy penetration hole may be accomplished by simultaneously etching the sacrificial insulation layer 130s and the interlayer insulating layer 132m by using an etching solution having a similar etching ratio to the sacrificial insulation layer 130s and the interlayer insulating layer 132m. However, as described above in FIG. 8 to FIG. 21, the upper insulating pattern 290 may include a different material, and therefore, although not shown in FIG. 31, an etching may be better performed in the direction in contact with the upper insulating pattern 290 positioned around the dummy penetration hole, e.g., in the second direction DR2. For example, an etching rate in the second direction DR2 may become greater such that than the upper insulating pattern 290 may be removed to a relatively larger extent or at a faster rate.

In addition, after expanding the diameter, a portion of the sacrificial insulation layer 130s in contact with each gate penetration hole and dummy penetration hole may be etched to secure a space for forming an insulating pattern. At this time, the etching of the sacrificial insulation layer 130s may be performed using an etching solution having a selectivity from the interlayer insulating layer 132m. Therefore, as shown in FIG. 31, the sacrificial insulation layer 130s may be selectively etched.

The subsequent process is explained with a drawing that enlarges the part marked by E in FIG. 31 for better comprehension and ease of description.

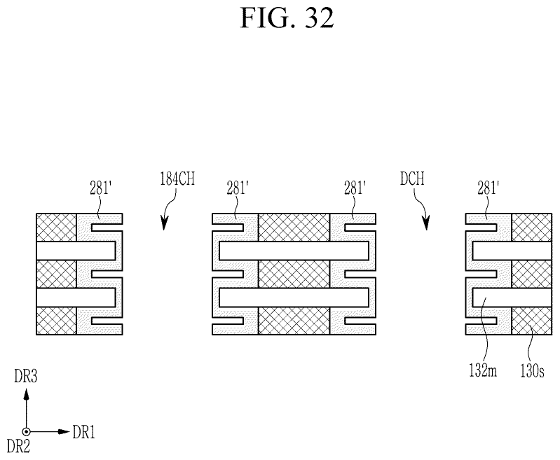

Referring to FIG. 32, a first preliminary insulating pattern 281′ is formed in the space where the sacrificial insulation layer 130s is etched. The first preliminary insulating pattern 281′ may include silicon oxide. At this time, the first preliminary insulating pattern 281′ may be formed along the surface of the space where the sacrificial insulation layer 130s is etched. Therefore, as shown in FIG. 32, the space where the sacrificial insulation layer 130s is etched may be not completely filled.

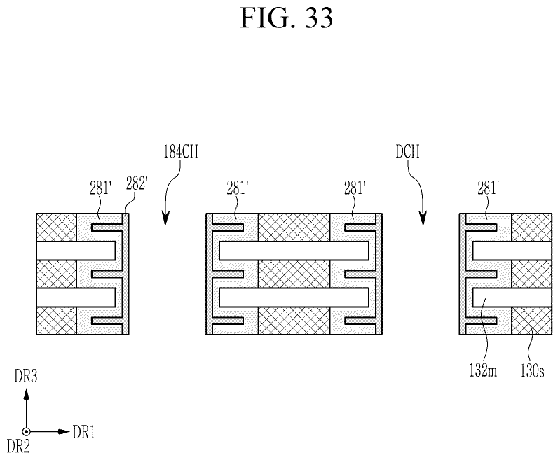

Next, referring to FIG. 33, a second preliminary insulating pattern 282′ is formed. The second preliminary insulating pattern 282′ may be formed on the first preliminary insulating pattern 281′. The second preliminary insulating pattern 282′ may include SiON. As shown in FIG. 33, the second preliminary insulating pattern 282′ may be formed while filling the space that was not completely filled by the first preliminary insulating pattern 281'.

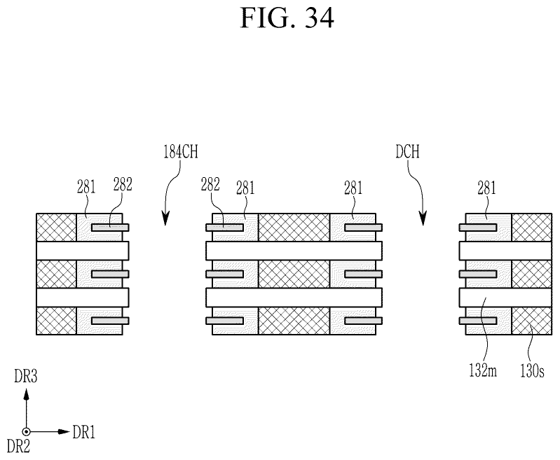

Referring to FIG. 34, the first preliminary insulating pattern 281′ and the second preliminary insulating pattern 282′ are partially removed thereby obtaining first and second insulating pattern 281 and 282. At this time, due to the difference in an etching ratio, a part of the second insulating pattern 282 may be positioned protruding from the first insulating pattern 281.

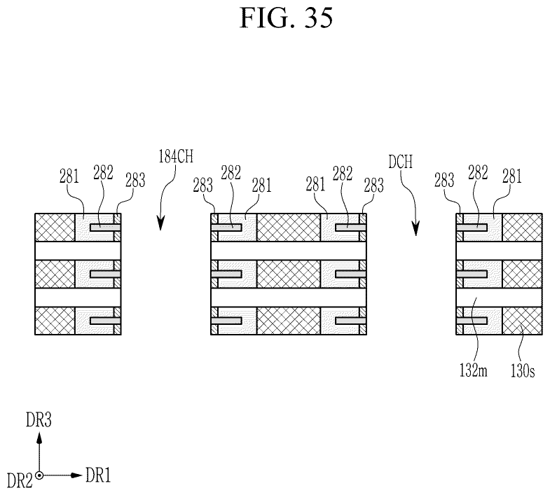

Next, referring to FIG. 35, a third insulating pattern 283 is formed. The formation of the third insulating pattern 283 may be formed by an etching process after forming a third preliminary insulating pattern on the entire side of the gate penetration hole 184CH and the dummy penetration hole DCH. This third insulating pattern 283 may fill the space where the sacrificial insulation layer 130s formed in the previous step was etched.

In the previous step, the first insulating pattern 281, the second insulating pattern 282, and the third insulating pattern 283 were formed in both the gate penetration hole 184CH and the dummy penetration hole DCH.

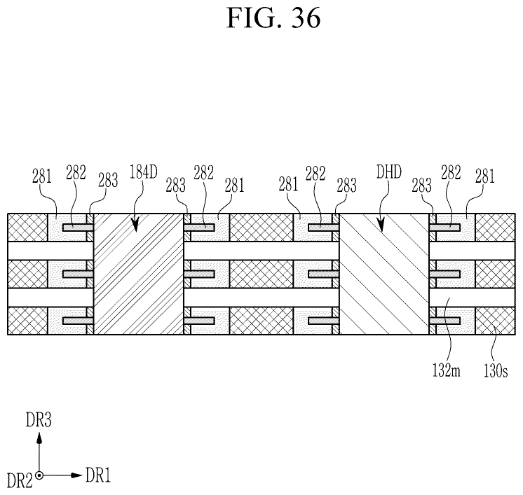

Next, referring to FIG. 36, a gate contact part dummy material 184D is formed inside the gate penetration hole 184CH, and a penetration hole dummy material DHD is formed inside the dummy penetration hole DCH.

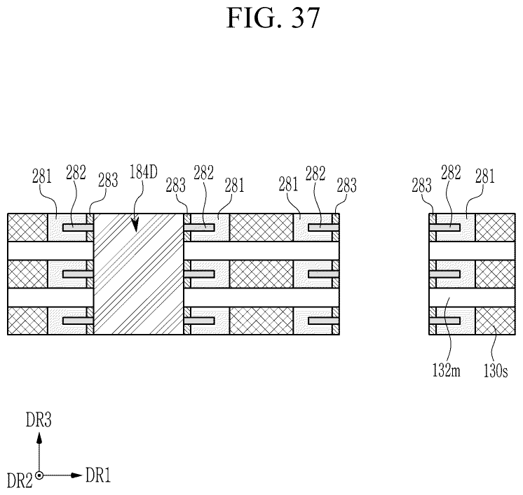

Referring to FIG. 37, the penetration hole dummy material DHD inside the dummy penetration hole is removed to expose the third insulating pattern 283.

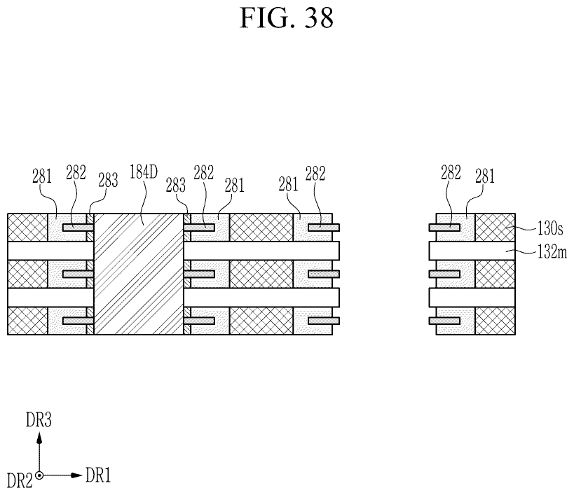

Referring to FIG. 38, the third insulating pattern 283 inside the dummy penetration hole is etched. The third insulating pattern 283 may be selectively removed only in the peripheral region of the dummy penetration hole through the etching step. FIG. 38 illustrates an embodiment in which the third insulating pattern 283 is completely etched, but this is only an example, and the third insulating pattern 283 may not be completely etched and the thickness may be reduced.

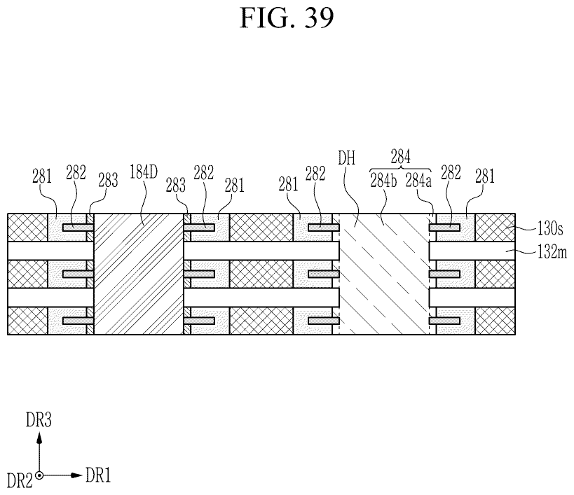

Next, referring to FIG. 39, the fourth insulating pattern 284 is filled inside the dummy penetration hole. At this time, the fourth insulating pattern 284 that fills the region from which the third insulating pattern 283 is removed in the previous step may form the first portion 284a of the fourth insulating pattern 284, and the fourth insulating pattern 284 that fills the vertical portion of the dummy penetration hole may form the second portion 284b of the fourth insulating pattern 284.

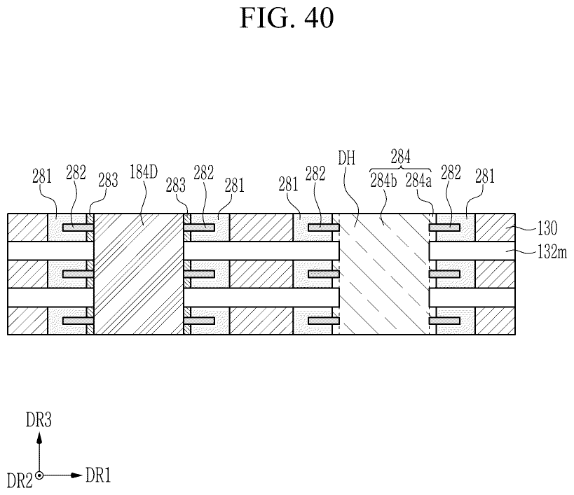

Referring to FIG. 40, the sacrificial insulation layer 130s is replaced with the gate electrode 130. Specifically, the first, the sacrificial insulation layer 130s may be removed, and the gate electrode 130 may be formed within the space from which the sacrificial insulation layer 130s has been removed. For example, after removing the sacrificial insulation layer 130s by using an etching process, a metal material such as tungsten (W), copper (Cu), or aluminum (Al) may be deposited to form the gate electrode 130.

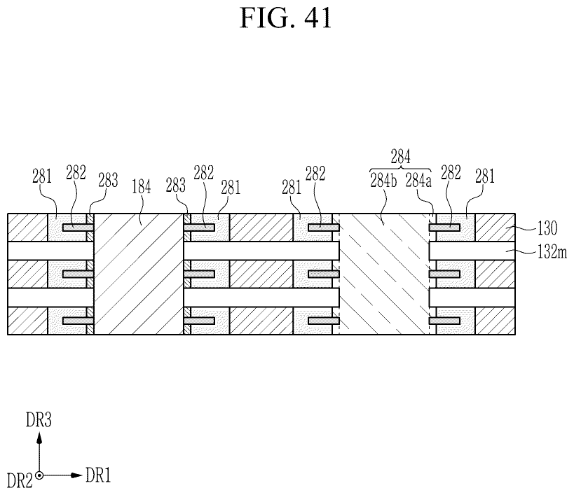

Next, referring to FIG. 41, the gate contact part dummy material 184D positioned inside the gate penetration hole is removed, and a conductive material is filled to form the gate contact part 184. Through this process, the semiconductor device as shown in FIG. 2 may be manufactured.

However, the manufacturing method described above is only an example, and the present invention is not limited thereto.

Next, an electronic system including the semiconductor device according to an embodiment of the present disclosure is described as follows with reference to FIGS. 42 and 43.

FIG. 42 is a schematic drawing of an electronic system including a semiconductor device according to an embodiment. FIG. 43 is a perspective view schematically illustrating an electronic system including a semiconductor device according to an embodiment.

An electronic system 1000 according to an embodiment, as shown in FIG. 43, may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive device (SSD), a Universal Serial Bus (USB), a computing system, a medical device or a communication apparatus including one or a plurality of semiconductor devices 1100.

The semiconductor device 1100 may be a non-volatile memory device, for example, a NAND flash memory device. An example of the semiconductor device 1100 is illustrated in FIG. 42. However, the semiconductor device 1100 may be one of the other examples described with reference to FIGS. 1 to 41. The semiconductor device 1100 may include a first structure 1100F (e.g., corresponding to the circuit region 200 described above) and a second structure 1100S (e.g., corresponding to the cell region 100 described above) on the first structure 1100F. In an exemplary embodiment, the first structure 1100F may be placed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first gate upper line UL1, a second gate lower line UL2, a first gate lower line LL1, a second gate lower line LL2, and a memory cell string CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to an embodiment.

In an exemplary embodiment, the lower transistors LT1 and LT2 may include a ground selection transistor, and the first and second gate lower lines LL1 and LL2 may be gate electrodes of the lower transistors LT1 and LT2, respectively. The word line WL may be the gate electrode of the memory cell transistor MCT, and the gate upper lines UL1 and UL2 may be the gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through the first connection wire 1115 extending to the second structure 1100S from the first structure 1100F. The bit line BL can be electrically connected to the page buffer 1120 through the second connection wire 1125, which extends to the second structure 1100S from the first structure 1100F.

In the first structure 1100F, the decoder circuit 1110 and the page buffer 1120 may perform a control operation on at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 via the input/output connection wire 1135 that extends from the first structure 1100F to the second structure 1100S.

The controller 1200 may include a processor 1210, a NAND controller 1220, and a host interface 1230. According to an embodiment, the electronic system 1000 may include a plurality of semiconductor devices 1100, in which case the controller 1200 may control the plurality of semiconductor devices 1100.

The processor 1210 may control the operation of the entire electronic system 1000, including the controller 1200. The processor 1210 may operate according to a predetermined firmware and control the NAND controller 1220 to access the semiconductor device 1100. The NAND controller 1220 may include a NAND interface 1221 that handles communication with the semiconductor device 1100. Through the NAND interface 1221, control instructions for controlling the semiconductor device 1100, data to be written to the memory cell transistor MCT of the semiconductor device 1100, data to be read from the memory cell transistor MCT of the semiconductor device 1100, etc. may be transmitted. The host interface 1230 may provide communication functions between the electronic system 1000 and an external host. When receiving a control instruction from an external host through the host interface 1230, the processor 1210 may respond to the control instruction and control the semiconductor device 1100.

An electronic system 2000 according to an embodiment, as shown in FIG. 43, may include a main substrate 2001, and a controller 2002, one or more semiconductor packages 2003, and a DRAM 2004 mounted on the main substrate 2001. The semiconductor package 2003 and the DRAM 2004 may be interconnected with the controller 2002 by the wire pattern 2005 formed on the main substrate 2001.

The main substrate 2001 may include a connector 2006 including a plurality of pins that couple to an external host. The number and arrangement of the plurality of pins in the connector 2006 may vary depending on the communication interface between the electronic system 2000 and the external host. In an exemplary embodiment, the electronic system 2000 may communicate with an external host via any one of following interfaces: Universal Serial Bus (USB), Peripheral Component Interconnect Express (PCI-Express), Serial Advanced Technology Attachment (SATA), or M-Phy for Universal Flash Storage (UFS). In an exemplary embodiment, the electronic system 2000 may be powered by a power supplied from an external host via the connector 2006. The electronic system 2000 may further include a Power Management Integrated Circuit (PMIC) that distributes the power supplied from the external host to the controller 2002 and the semiconductor package 2003.

The controller 2002 may write a data to or read a data from the semiconductor package 2003, and improve the operation speed of the electronic system 2000.

The DRAM 2004 may be a buffer memory to alleviate the speed difference between the semiconductor package 2003, which is the data storage space, and the external host. The DRAM 2004 included in the electronic system 2000 may also function as a type of a cache memory and provide a space to temporarily store a data in control operations for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include a first and a second semiconductor packages 2003a and 2003b which are spaced apart from each other. The first and second semiconductor packages 2003a and 2003b may each be a semiconductor package including a plurality of semiconductor chips 2200. Each of the first and second semiconductor packages 2003a and 2003b may include a package substrate 2100, a semiconductor chip 2200 on the package substrate 2100, an adhesive layer 2300 disposed on the bottom surface of each of the semiconductor chips 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 42. Each semiconductor chip 2200 may include a gate stacking structure 3210 and a channel structure 3220. The semiconductor chip 2200 may include the semiconductor device described above.

In an exemplary embodiment, the connection structure 2400 may be a bonding wire that electrically connects the input/output pad 2210 and the package upper pad 2130. Therefore, in each of the first and second semiconductor packages 2003a and 2003b, the semiconductor chips 2200 may be electrically connected to each other in a bonding wire manner and may be electrically connected to the package upper pad 2130 of the package substrate 2100. According to an embodiment, in each of the first and second semiconductor packages 2003a and 2003b, the semiconductor chips 2200 may be electrically connected to each other by a connection structure including a through silicon via (TSV), instead of a connection structure 2400 of a bonding wire-type.

In an exemplary embodiment, the controller 2002 and the semiconductor chip 2200 may be included in a single package. For example, the controller 2002 and the semiconductor chip 2200 may be mounted on a separate interposer substrate from the main substrate 2001, and the controller 2002 and the semiconductor chip 2200 may be connected to each other by wires formed on the interposer substrate.

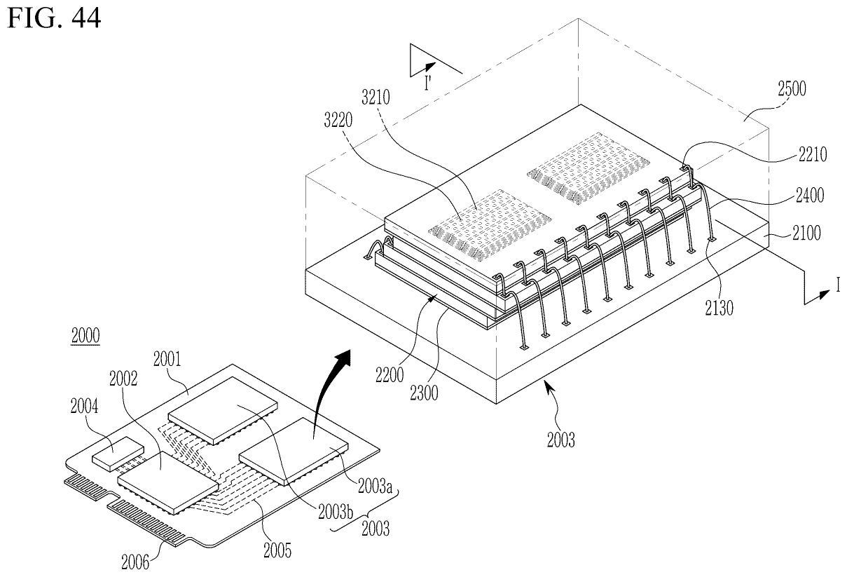

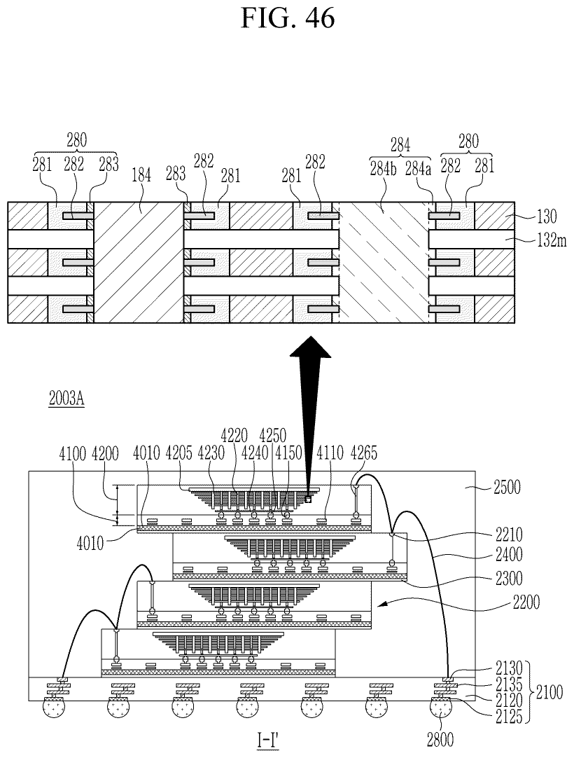

FIG. 44 is a perspective view schematically illustrating an electronic system, and FIGS. 45 and 46 are cross-sectional views schematically showing semiconductor packages according to embodiments. FIG. 44 and FIG. 45 illustrate exemplary embodiments of the semiconductor package 2003, and conceptually illustrate regions cut along section a line I-I′ of the semiconductor package 2003 of FIG. 44.

Referring to FIGS. 44 and 45, in the semiconductor package 2003, the package substrate 2100 may be a printed circuit board. The package substrate 2100 may include a package substrate body portion 2120, a package upper pad 2130 disposed on the upper surface of the package substrate body portion 2120, a lower pad 2125 disposed on the lower surface of the package substrate body portion 2120 or exposed through the lower surface, and an inner wire 2135 electrically connecting the upper pad 2130 and the lower pad 2125 within the package substrate body portion 2120. The upper pad 2130 may be electrically connected to the connection structure 2400. The lower pad 2125 may be connected to a wire pattern 2005 of the main substrate 2001 of the electronic system 2000 as shown in FIG. 44 via a conductive connection 2800.

The semiconductor chip 2200 may each include a semiconductor substrate 3010 and a first structure 3100 and a second structure 3200 sequentially stacked on the semiconductor substrate 3010. The first structure 3100 may include a peripheral circuit region including a peripheral wire 3110. The second structure 3200 may include a common source line 3205, a gate stacking structure 3210 on the common source line 3205, a channel structure 3220 and a separation structure 3230 passing through the gate stacking structure 3210, a bit line 3240 electrically connected to the channel structure 3220, and a gate connection wire electrically connected to a word line of the gate stacking structure 3210.

Referring back to FIG. 42, in the semiconductor chip 2200 or the semiconductor device 1100 according to an embodiment, the insulating pattern 280 in contact with the gate contact part 184 may include a first insulating pattern 281, a second insulating pattern 282 positioned between the first insulating pattern 281, and a third insulating pattern 283 capping a space in which the insulating pattern 280 is formed, and the insulating pattern 280 in contact with the dummy structure DH may include a first insulating pattern 281 and a second insulating pattern 282 positioned between the first insulating pattern 281, and may not include a third insulating pattern 283. Alternatively, when the insulating pattern 280 in contact with the dummy structure DH includes the third insulating pattern 283, the horizontal thickness of the third insulating pattern 283 in contact with the dummy structure DH may be thinner than the horizontal thickness of the third insulating pattern 283 in contact with the gate contact part 184.

Each of the semiconductor chips 2200 may include a penetration wire 3245 that is electrically connected to the peripheral wire 3110 of the first structure 3100 and extends into the second structure 3200. The penetration wire 3245 may penetrate the gate stacking structure 3210 and may be further positioned on the outside of the gate stacking structure 3210. Each of the semiconductor chips 2200 may further include an input/output connection wire 3265 that is electrically connected to the peripheral wire 3110 of the first structure 3100 and extends into the second structure 3200, and an input/output pad 2210 that is electrically connected to the input/output connection wire 3265.

In an exemplary embodiment, a plurality of semiconductor chips 2200 in the semiconductor package 2003 may be electrically connected to each other by a connection structure 2400 in the form of bonding wires. As another example, the plurality of semiconductor chip 2200 or a plurality of parts constituting the same may be electrically connected by a connection structure including a through silicon via (TSV).

Referring to FIG. 46, in the semiconductor package 2003A, each semiconductor chip 2200 may include a semiconductor substrate 4010, a first structure 4100 on the semiconductor substrate 4010, and a second structure 4200 bonded to the first structure 4100 by a wafer bonding method on the first structure 4100.

The first structure 4100 may include a peripheral circuit region including a peripheral wire 4110 and a first junction structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second junction structure 4250 electrically connected to word lines of the channel structure 4220 and the gate stacking structure 4210, respectively. For example, the second junction structure 4250 may be electrically connected to the channel structure 4220 and the word line WL, respectively, through a gate connection wire, which is electrically connected to the bit line 4240 and the word line WL, which is electrically connected to the channel structure 4220. The first junction structure 4150 of the first structure 4100 and the second junction structure 4250 of the second structure 4200 may be bonded while being in contact with each other. The junction portion of the first junction structure 4150 and the second junction structure 4250 may be formed of, for example, copper (Cu).

Referring back to FIG. 42, in the semiconductor chip 2200 or the semiconductor device 1100 according to an embodiment, the insulating pattern 280 in contact with the gate contact part 184 may include a first insulating pattern 281, a second insulating pattern 282 positioned between the first insulating pattern 281, and a third insulating pattern 283 capping a space in which the insulating pattern 280 is formed, and the insulating pattern 280 in contact with the dummy structure DH may include a first insulating pattern 281 and a second insulating pattern 282 positioned between the first insulating pattern 281, and may not include a third insulating pattern 283. Alternatively, when the insulating pattern 280 in contact with the dummy structure DH includes the third insulating pattern 283, the horizontal thickness of the third insulating pattern 283 in contact with the dummy structure DH may be thinner than the horizontal thickness of the third insulating pattern 283 in contact with the gate contact part 184.

Each of the semiconductor chips 2200 may further include an input/output pad 2210 and an input/output connection wire 4265 beneath the input/output pad 2210. The input/output connection wire 4265 may be electrically connected to some of the second junction structures 4250.

In an embodiment, the plurality of semiconductor chips 2200 in the semiconductor package 2003 may be electrically connected to each other by a connection structure 2400 in a form of a bonding wire. As another example, a plurality of semiconductor chip 2200 or a plurality of parts constituting the same may be electrically connected by a connection structure including a through silicon via.

Referring to drawings described above, according to some embodiments, a semiconductor device and an electronic system including a semiconductor device includes a substrate 210 including a peripheral circuit region 200, and a cell region 100 positioned adjacent to the peripheral circuit region 200 and including a cell array region 102 and a connection region 104. The cell region 100 may include a gate stack 120 including interlayer insulating layers 132m and gate electrodes 130 alternately stacked on the substrate 210. The cell region 100 may further include a channel pattern CH positioned in the cell array region 102 and penetrating the gate stack 120. The cell region 100 may further include a gate contact pattern 184 that is electrically connected to the peripheral circuit region and formed through the gate stack 120 in the connection region 104. The cell region 100 may further include a dummy pattern DH penetrating the gate stack 120 and being electrically insulated from the peripheral circuit region 200 and the gate electrodes 130.

The cell region 100 may further include a set of insulating patterns adjacent to the gate contact pattern 184 and the dummy pattern DH. The set of insulating patterns may include first insulating patterns 281 (2811 and 2812) positioned along circumferences of spaces in which the set of insulating patterns are formed, each of the first insulating patterns 281 having a recess, second insulating patterns 282 (2821 and 2822) each positioned in a corresponding one of recesses of the first insulating patterns 281, and third insulating patterns 283 (2831 and 2832) each filling a corresponding one of the spaces in which the set of insulating patterns are formed.

The first insulating patterns 281 may include first and second subsets 2811 and 2812 of the first insulating patterns 281. Each of the first subset 2811 of insulating patterns 281 may be positioned between a corresponding one of the gate electrodes 130 and the gate contact pattern 184, and each of the second subset 2812 of insulating patterns 281 may be positioned between a corresponding one of the gate electrodes 130 and the dummy pattern DH.

The second insulating patterns 282 may include third and fourth subsets 2821 and 2822 of the second insulating patterns 282. Each of the third subset 2821 of insulating patterns 281 may be positioned between a corresponding one of the gate electrodes 130 and the gate contact pattern 184. Each of the fourth subset 2822 of insulating patterns 282 may be positioned between a corresponding one of the gate electrodes 130 and the dummy pattern DH.

The third insulating patterns 283 may include fifth and sixth subsets 2831 and 2832 of the third insulating patterns 283. Each of the fifth subset 2831 of insulating patterns 283 may be positioned between a corresponding one of the gate electrodes 130 and the gate contact pattern 184, and each of the sixth subset 2832 of insulating patterns 283 may be positioned between a corresponding one of the gate electrodes 130 and the dummy pattern DH.

The set of insulating patterns may be interposed between the dummy pattern DH and the gate electrodes 130. The gate electrodes 130 may include a connection gate electrode 130c and the remaining gate electrodes. The gate contact pattern 184 may be electrically connected to the connection gate electrode 130c and may be insulated from the remaining gate electrodes by the set of insulating patterns.

The third insulating patterns 283 may include SiN (silicon nitride), and a horizontal thickness of each of the fifth subset 2831 of insulating patterns 283 in a direction parallel to the substrate may be thicker than a horizontal thickness of each of the sixth subset 2832 of insulating patterns 283 in the direction parallel to the substrate 210 in a cross sectional view.

The connection region 104 may include first and second connection regions which are divided by a vertical plane intersecting the dummy pattern DH, and a vertical thickness of the first connection region may be greater than that of the second connection region such that the gate stack has a step shape in a cross sectional view, as shown in FIG. 2 and so on.

Referring to drawings described above, according to some embodiments, a semiconductor device and an electronics system including a semiconductor device includes a substrate 210 including a peripheral circuit region 200, and a cell region 100. The cell region 100 may include a set of insulating patterns, which are in contact with a gate contact pattern 184.

The set of insulating patterns may include a first group of insulating patterns 2811, 2821 and 283 and a second group of insulating patterns 2812 and 2822. The first group of insulating patterns may be interposed between the dummy pattern DH and the gate electrodes 130. The second group of insulating patterns may be in contact with the dummy pattern DH and does not include SiN.

The first group of insulating patterns may include a first sub-group of insulating patterns 2811, a second sub-group of insulating patterns 2821 and a third sub-group of insulating patterns 283. The second group of insulating patterns may include a fourth sub-group of insulating patterns 2812, a fifth sub-group of insulating patterns 2822. The plurality of protrusion portions 280a may be in contact with the second group of insulating patterns.

The first sub-group of insulating patterns may be positioned along circumferences of first spaces in which the first group of insulating patterns are formed, each of the first sub-group of insulating patterns having a first recess. The second sub-group of insulating patterns each may be positioned in a corresponding one of the first recesses of the first sub-group of insulating patterns. The third sub-group of insulating patterns may include SiN. The fourth sub-group of insulating patterns may include silicon oxide. The fifth sub-group of insulating patterns may include SiON.

The first group of insulating patterns may include more nitrogen per unit volume than the second group of insulating patterns. The fifth sub-group of insulating patterns may include more nitrogen per unit volume than the fourth sub-group of insulating patterns. The fifth sub-group of insulating patterns may include more nitrogen per unit volume than the dummy pattern. For example, silicon nitride may contain more nitrogen per unit volume than silicon oxynitride. Compared to silicon oxynitride, silicon nitride contains a significantly greater atomic percentage of nitrogen. Due to its stoichiometry, silicon nitride may possess a higher nitrogen concentration relative to silicon oxynitride, which contains both oxygen and nitrogen. Silicon oxynitride may contain more nitrogen per unit volume than silicon oxide.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device comprising:
a substrate including a peripheral circuit region; and
a cell region positioned adjacent to the peripheral circuit region and including a cell array region and a connection region,
wherein:
the cell region includes:
a gate stack including interlayer insulating layers and gate electrodes alternately stacked on the substrate,
a channel pattern positioned in the cell array region and penetrating the gate stack,
a gate contact pattern that is electrically connected to the peripheral circuit region and formed through the gate stack in the connection region,
a dummy pattern penetrating the gate stack and being insulated from the peripheral circuit region and the gate electrodes, and
a set of insulating patterns adjacent to the gate contact pattern and the dummy pattern,
the set of insulating patterns includes:
first insulating patterns positioned along circumferences of spaces in which the set of insulating patterns are formed, each of the first insulating patterns having a recess,
second insulating patterns each positioned in a corresponding one of recesses of the first insulating patterns, and
third insulating patterns each filling a corresponding one of the spaces in which the set of insulating patterns are formed,
the first insulating patterns include first and second subsets of the first insulating patterns, each insulating pattern of the first subset of insulating patterns is positioned between a corresponding one of the gate electrodes and the gate contact pattern, and each insulating pattern of the second subset of insulating patterns is positioned between a corresponding one of the gate electrodes and the dummy pattern,
the second insulating patterns include third and fourth subsets of the second insulating patterns, each insulating pattern of the third subset of insulating patterns is positioned between a corresponding one of the gate electrodes and the gate contact pattern, and each insulating pattern of the fourth subset of insulating patterns is positioned between a corresponding one of the gate electrodes and the dummy pattern,
the third insulating patterns include fifth and sixth subsets of the third insulating patterns, each insulating pattern of the fifth subset of insulating patterns is positioned between a corresponding one of the gate electrodes and the gate contact pattern, and each insulating pattern of the sixth subset of insulating patterns is positioned between a corresponding one of the gate electrodes and the dummy pattern,
the set of insulating patterns are interposed between the dummy pattern and the gate electrodes,
the gate electrodes include a connection gate electrode and remaining gate electrodes,
the gate contact pattern is electrically connected to the connection gate electrode and is insulated from the remaining gate electrodes by the set of insulating patterns,
the third insulating patterns include SiN (silicon nitride), and
a horizontal thickness of each insulating pattern of the fifth subset of insulating patterns in a direction parallel to the substrate is thicker than a horizontal thickness of each insulating pattern of the sixth subset of insulating patterns in the direction parallel to the substrate in a cross sectional view.

2. The semiconductor device of claim 1, wherein:
the first insulating patterns include silicon oxide, and
the second insulating patterns include SiON (silicon oxynitride).

3. The semiconductor device of claim 1, wherein the horizontal thickness of each insulating pattern of the fifth subset of insulating patterns is 1 nm to 20 nm.

4. The semiconductor device of claim 1, wherein a planar diameter of the dummy pattern is larger than a planar diameter of the gate contact pattern in a plane parallel to the substrate.

5. The semiconductor device of claim 4, wherein the planar diameter of the dummy pattern is 10% to 15% larger than the planar diameter of the gate contact pattern.

6. The semiconductor device of claim 1, wherein:
the connection region includes first and second connection regions which are divided by a vertical plane intersecting the dummy pattern, and
a vertical thickness of the first connection region is greater than that of the second connection region such that the gate stack has a step shape in a cross sectional view.

7. The semiconductor device of claim 6, wherein a planar diameter of the dummy pattern in a first direction is different from a planar diameter of the dummy pattern in a second direction intersecting the first direction in a plane parallel to the substrate.

8. The semiconductor device of claim 1, further comprising an upper insulating pattern positioned along an upper surface of the gate stack,
wherein, in a cross-section, the dummy pattern is in contact with both the gate stack and the upper insulating pattern.

9. A semiconductor device comprising:
a substrate including a peripheral circuit region; and
a cell region positioned adjacent to the peripheral circuit region and including a cell array region and a connection region,
wherein:
the cell region includes:
a gate stack including interlayer insulating layers and gate electrodes alternately stacked on the substrate,
a channel pattern positioned in the cell array region and penetrating the gate stack,
a gate contact pattern that is electrically connected to the peripheral circuit region and formed through the gate stack in the connection region, and
a dummy pattern penetrating the gate stack and being insulated from the peripheral circuit region and the gate electrodes,
a set of insulating patterns is in contact with the gate contact pattern,
the gate contact pattern includes SiN,
the set of insulating patterns include a first group of insulating patterns and a second group of insulating patterns,
first group of insulating patterns are interposed between the dummy pattern and the gate electrodes,
the gate electrodes include a connection gate electrode and remaining gate electrodes,
the gate contact pattern is electrically connected to the connection gate electrode and is insulated from the remaining gate electrodes by the set of insulating patterns, and
the second group of insulating patterns are in contact with the dummy pattern and do not include SiN.

10. The semiconductor device of claim 9, wherein:
the first group of insulating patterns are adjacent to the gate contact pattern,
the first group of insulating patterns include:
a first sub-group of insulating patterns positioned along circumferences of first spaces in which the first group of insulating patterns are formed, each insulating pattern of the first sub-group of insulating patterns having a first recess,
a second sub-group of insulating patterns each positioned in a corresponding one of the first recesses of the first sub-group of insulating patterns, and
a third sub-group of insulating patterns each filling a corresponding one of the first spaces in which insulating patterns of the first group of insulating patterns are formed, and
the third sub-group of insulating patterns include SiN.

11. The semiconductor device of claim 10, wherein:
the second group of insulating patterns are positioned adjacent to the dummy pattern, and
the second group of insulating patterns include:
a fourth sub-group of insulating patterns positioned along circumferences of spaces in which the second group of insulating patterns are formed, each insulating pattern of the fourth sub-group of insulating patterns having a second recess, and
a fifth sub-group of insulating patterns each positioned in a corresponding one of the second recesses of the fourth sub-group of insulating patterns, and
the dummy pattern is in contact with the second group of insulating patterns.

12. The semiconductor device of claim 11, wherein:
the fourth sub-group of insulating patterns include silicon oxide,
the fifth sub-group of insulating patterns include SiON, and
the dummy pattern includes silicon oxide.

13. The semiconductor device of claim 11, wherein:
the dummy pattern includes an elongated insulating body and a plurality of protrusion portions,
the elongated insulating body extends vertically, and
the plurality of protrusion portions are in contact with the second group of insulating patterns.

14. The semiconductor device of claim 9, wherein a planar diameter of the dummy pattern is larger than a planar diameter of the gate contact pattern in a plane parallel to the substrate.

15. The semiconductor device of claim 14, wherein the planar diameter of the dummy pattern is larger than the planar diameter of the gate contact pattern by 10% to 15%.

16. The semiconductor device of claim 14, wherein:
the connection region includes first and second connection regions which are divided by a vertical plane intersecting the dummy pattern, and
a vertical thickness of the first connection region is greater than that of the second connection region such that the gate stack includes a step shape in a cross sectional view.

17. The semiconductor device of claim 16, wherein a planar diameter of the dummy pattern in a first direction is different from a planar diameter of the dummy pattern in a second direction intersecting the first direction in a plane parallel to the substrate.

18. A semiconductor device comprising:
a substrate including a peripheral circuit region; and
a cell region positioned adjacent to the peripheral circuit region and including a cell array region and a connection region,
wherein:
the cell region includes:
a gate stack including interlayer insulating layers and gate electrodes alternately stacked on the substrate,
a channel pattern positioned in the cell array region and penetrating the gate stack,
a gate contact pattern that is electrically connected to the peripheral circuit region and formed through the gate stack in the connection region, and
a dummy pattern penetrating the gate stack and being insulated from the peripheral circuit region and the gate electrodes,
a set of insulating patterns is in contact with the gate contact pattern,
the set of insulating patterns include a first group of insulating patterns and a second group of insulating patterns,
the first group of insulating patterns are interposed between the dummy pattern and the gate electrodes,
the gate electrodes include a connection gate electrode and remaining gate electrodes,
the gate contact pattern is electrically connected to the connection gate electrode and is insulated from the remaining gate electrodes by the set of insulating patterns,
the second group of insulating patterns are in contact with the dummy pattern, and
the gate contact pattern includes more nitrogen per unit volume than the second group of insulating patterns.

19. The semiconductor device of claim 18, wherein:
the second group of insulating patterns are positioned adjacent to the dummy pattern,
the second group of insulating patterns include:
a first sub-group of insulating patterns positioned along circumferences of spaces in which the second group of insulating patterns are formed, each insulating pattern of the first sub-group of insulating patterns having a second recess, and
a second sub-group of insulating patterns each positioned in a corresponding one of the second recesses of the first sub-group of insulating patterns, and the dummy pattern is in contact with the second group of insulating patterns.

20. The semiconductor device of claim 19, wherein:
the second sub-group of insulating patterns include more nitrogen per unit volume than the first sub-group of insulating patterns, and
the second sub-group of insulating patterns include more nitrogen per unit volume than the dummy pattern.
